(19) United States
(12) Patent Application Publication
(10) Pub. No.: US 2024/0396294 A1
(43) Pub. Date: Nov. 28, 2024

(54) LIGHT EMITTING DEVICE, METHOD FOR MANUFACTURING LIGHT EMITTING DEVICE, AND DISTANCE MEASURING DEVICE

(71) Applicant: SONY SEMICONDUCTOR SOLUTIONS CORPORATION, KANAGAWA (JP)

(72) Inventors: TOSHIKAZU IJIRO, KUMAMOTO (JP); HIROYASU MATSUGAI, KANAGAWA (JP)

(21) Appl. No.: 18/695,413

(22) PCT Filed: Aug. 25, 2022
(86) PCT No.: PCT/JP2022/031981

§ 371 Date: Mar. 26, 2024

(30) Foreign Application Priority Data
Oct. 7, 2021 (JP) 2021-165608

(51) Int. Cl. H01S 5/02326; G01S 7/481; G01S 17/08; H01S 5/02253; H01S 5/42

(52) U.S. Cl. CPC H01S 5/02326; G01S 7/4815; G01S 17/08; H01S 5/02253; H01S 5/423

(57) ABSTRACT

Provided are a light emitting device, a method for manufacturing the light emitting device, and a distance measuring device capable of suitably allowing light emitted from a light emitting element to be incident on a lens. A light emitting device of the present disclosure includes: a substrate; a plurality of light emitting elements provided on a first surface side of the substrate; and a plurality of lenses provided on a second surface side of the substrate, in which the substrate includes a first groove having a shape surrounding a first lens included in the plurality of lenses, the first groove has a first side surface provided on the first lens side and a second side surface provided on an opposite side of the first lens, and an inclination angle of the first side surface with respect to the first surface or the second surface is 80 degrees or more and 100 degrees or less.

### TECHNICAL FIELD

The present disclosure relates to a light emitting device, a method for manufacturing a light emitting device, and a distance measuring device.

### BACKGROUND ART

As a type of semiconductor laser, a surface-emitting laser such as a vertical cavity surface emitting laser (VCSEL) is known. In general, in a light emitting device utilizing a surface-emitting laser, a plurality of light emitting elements is provided in a two-dimensional array on a front surface or a back surface of a substrate.

### CITATION LIST

### Patent Document

Patent Document 1: Japanese Patent Application Laid-Open No. 2020-129630
Patent Document 2: Japanese Patent Application Laid-Open No. 2003-291406
Patent Document 3: Japanese Patent Application Laid-Open No. 2001-221975
Patent Document 4: Japanese Patent Application Laid-Open No. 2005-070807
Patent Document 5: Japanese Patent Application Laid-Open No. 2019-165198
Patent Document 6: Japanese Patent Application Laid-Open No. 2002-185071

### SUMMARY OF THE INVENTION

### Problems to be Solved by the Invention

In the light emitting device as described above, crosstalk occurs when light emitted from a certain light emitting element is directed toward another lens without being directed toward the corresponding lens. Such light is called stray light. It is desirable to suppress generation of stray light.

On the other hand, when the light emitted from a certain light emitting element is reflected for some reason before reaching the corresponding lens, light to be emitted to the outside of the light emitting device decreases or disappears. Such light is called return light. It is desirable to suppress generation of return light.

Therefore, the present disclosure provides a light emitting device, a method for manufacturing the light emitting device, and a distance measuring device capable of suitably allowing light emitted from a light emitting element to be incident on a lens.

### Solutions to Problems

A light emitting device of a first aspect of the present disclosure includes: a substrate; a plurality of light emitting elements provided on a first surface side of the substrate; and a plurality of lenses provided on a second surface side of the substrate, in which the substrate includes a first groove having a shape surrounding a first lens included in the plurality of lenses, the first groove has a first side surface provided on the first lens side and a second side surface provided on an opposite side of the first lens, and an inclination angle of the first side surface with respect to the first surface or the second surface is 80 degrees or more and 100 degrees or less. As a result, for example, the light emitted from the light emitting element can be totally reflected by the first side surface, and this light can be suitably incident on the first lens.

Further, in the first aspect, an inclination angle of the second side surface with respect to the first surface or the second surface may be 80 degrees or more and 100 degrees or less. As a result, for example, the light emitted from the light emitting element can be totally reflected by the second side surface, and this light can be suitably incident on the first lens, and the cross-sectional shape of the first groove can be made into a line-symmetric shape or a shape close to line symmetry.

Further, in the first aspect, the first groove may have a bottom surface between the first side surface and the second side surface. As a result, for example, by forming the first groove as a rectangular groove, the inclination angle of the first side surface can be set to 80 degrees or more and 100 degrees or less.

Further, in the first aspect, the first side surface and the second side surface may be in contact with each other in the first groove. As a result, for example, by forming the first groove as a V-shaped groove, the inclination angle of the first side surface can be set to 80 degrees or more and 100 degrees or less.

In addition, in the first aspect, the first groove may penetrate the substrate. As a result, for example, it is possible to suppress light from passing through the gap between the first surface of the substrate and the groove surface of the first groove.

Further, in the first aspect, the first groove may have a depth at which light emitted from the light emitting element does not enter a deepest portion of a groove surface of the first groove. As a result, for example, it is possible to suppress light from passing through the gap between the first surface of the substrate and the groove surface of the first groove.

Furthermore, in the first aspect, the first groove may have a width equal to or larger than a wavelength of light emitted from the light emitting element. As a result, for example, it is possible to suppress transmission of light through the first groove.

Further, in the first aspect, the first groove may have a shape in which light emitted from the light emitting element is totally reflected by the first side surface. As a result, for example, it is possible to suppress light from coming out of the substrate from the first side surface.

In addition, the light emitting device in the first aspect may further include an insulating film provided in the first groove. As a result, for example, the first groove can be protected by the insulating film, and the refractive index in the first groove can be adjusted.

Furthermore, in the first aspect, a refractive index of the insulating film may be 2.3 or less. Thus, for example, the light incident on the first side surface can be totally reflected.

Further, in the first aspect, the substrate may further include a second groove having a shape surrounding a second lens included in the plurality of lenses, the second groove may have a third side surface provided on the second lens side and a fourth side surface provided on an opposite side of the second lens, and an inclination angle of the third side surface with respect to the first surface or the second surface may be 80 degrees or more and 100 degrees or less. As a result, for example, the light emitted from the light emitting element can be totally reflected by the third side surface, and this light can be suitably incident on the second lens.

Further, in the first aspect, an inclination angle of the fourth side surface with respect to the first surface or the second surface may be 80 degrees or more and 100 degrees or less. As a result, for example, the light emitted from the light emitting element can be totally reflected by the fourth side surface, and this light can be suitably incident on the second lens, and the cross-sectional shape of the second groove can be made into a line-symmetric shape or a shape close to line symmetry.

Further, in the first aspect, the second groove may be separated from the first groove. Thus, for example, these grooves can be set in a simple shape.

Further, in the first aspect, the second groove may be connected to the first groove. This makes it possible to save a space for arranging these grooves, for example.

Furthermore, in this first aspect, the plurality of lenses may be provided on the second surface of the substrate as parts of the substrate. Thus, for example, the lens can be easily formed by processing the substrate.

A light emitting device of a second aspect of the present disclosure includes: a substrate; a plurality of light emitting elements provided on a first surface side of the substrate; and a plurality of lenses provided on a second surface side of the substrate, in which the substrate includes a groove provided between the lenses, and the groove has a depth at which light emitted from the light emitting element does not enter a deepest portion of a groove surface of the groove. As a result, for example, the light emitted from the light emitting element can be suppressed from becoming stray light or return light, and this light can be suitably incident on the first lens.

A method for manufacturing a light emitting device of a third aspect of the present disclosure includes: forming a plurality of light emitting elements on a first surface side of a substrate; forming a plurality of lenses on a second surface side of the substrate; and forming, in the substrate, a first groove having a shape surrounding a first lens included in the plurality of lenses, in which the first groove is formed to have a first side surface provided on the first lens side and a second side surface provided on an opposite side of the first lens, and an inclination angle of the first side surface with respect to the first surface or the second surface is set to 80 degrees or more and 100 degrees or less. As a result, for example, the light emitted from the light emitting element can be totally reflected by the first side surface, and this light can be suitably incident on the first lens.

Further, in the third aspect, the first groove may be formed in the substrate from the second surface side of the substrate. As a result, for example, the first groove can be formed after the above-described substrate is bonded to a support substrate.

Further, in the third aspect, the first groove may be formed in the substrate from the first surface side of the substrate. As a result, for example, the first groove can be formed before the above-described substrate is bonded to a support substrate.

In addition, the method for manufacturing a light emitting device in the third aspect may further include forming a light-shielding film covering a part of an upper surface of each of the lenses on each of the lenses. Thus, for example, the performance of the lens can be adjusted by the light-shielding film.

A distance measuring device of a fifth aspect of the present disclosure includes: a light emitting unit that includes a plurality of light emitting elements that generate light and irradiates a subject with the light from the light emitting elements; a light receiving unit that receives light reflected from the subject; and a distance measuring unit that measures a distance to the subject on a basis of the light received by the light receiving unit, in which the light emitting device includes: a substrate; the plurality of light emitting elements provided on a first surface side of the substrate; and a plurality of lenses provided on a second surface side of the substrate, the substrate includes a first groove having a shape surrounding a first lens included in the plurality of lenses, the first groove has a first side surface provided on the first lens side and a second side surface provided on an opposite side of the first lens, and an inclination angle of the first side surface with respect to the first surface or the second surface is 80 degrees or more and 100 degrees or less. As a result, for example, the light emitted from the light emitting element can be totally reflected by the first side surface, and this light can be suitably incident on the first lens.

A distance measuring device of a sixth aspect of the present disclosure includes: a light emitting unit that includes a plurality of light emitting elements that generate light and irradiates a subject with the light from the light emitting elements; a light receiving unit that receives light reflected from the subject; and a distance measuring unit that measures a distance to the subject on a basis of the light received by the light receiving unit, in which the light emitting unit includes: a substrate; a plurality of light emitting elements provided on a first surface side of the substrate; and a plurality of lenses provided on a second surface side of the substrate, the substrate includes a groove provided between the lenses, and the groove has a depth at which light emitted from the light emitting element does not enter a deepest portion of a groove surface of the groove. As a result, for example, the light emitted from the light emitting element can be suppressed from becoming stray light or return light, and this light can be suitably incident on the first lens.

### BRIEF DESCRIPTION OF DRAWINGS

FIG. 1 is a block diagram illustrating a configuration example of a distance measuring device of a first embodiment.

FIG. 2 is a diagram for explaining a structured light (STL) method of the first embodiment.

FIG. 3 is a cross-sectional view illustrating an example of a structure of a light emitting device of the first embodiment.

FIG. 4 is a cross-sectional view illustrating a structure of the light emitting device illustrated in B of FIG. 3.

FIG. 5 is a cross-sectional view and a plan view illustrating a structure of the light emitting device of the first embodiment.

FIG. 6 is a cross-sectional view illustrating a structure of a light emitting device of a comparative example of the first embodiment.

FIG. 7 is a cross-sectional view and a plan view illustrating a structure of a light emitting device of a modification of the first embodiment.

FIG. 8 is a plan view illustrating a structure of a light emitting device of another modification of the first embodiment.

FIG. 9 is a cross-sectional view illustrating a structure of a light emitting device of another modification of the first embodiment.

FIG. 10 is a cross-sectional view illustrating a structure of a light emitting device of another modification of the first embodiment.

FIG. 11 is a cross-sectional view illustrating a structure of a light emitting device of another modification of the first embodiment.

FIG. 12 is a cross-sectional view (1/2) illustrating a method for manufacturing a light emitting device of the first embodiment.

FIG. 13 is a cross-sectional view (2/2) illustrating the method for manufacturing a light emitting device of the first embodiment.

FIG. 14 is a cross-sectional view illustrating a structure of a light emitting device of a second embodiment.

FIG. 15 is a cross-sectional view illustrating a structure of a light emitting device of a comparative example of the second embodiment.

FIG. 16 is a cross-sectional view illustrating a structure of a light emitting device of a modification of the second embodiment.

FIG. 17 is a cross-sectional view (1/6) illustrating a method for manufacturing a light emitting device of the second embodiment.

FIG. 18 is a cross-sectional view (2/6) illustrating the method for manufacturing a light emitting device of the second embodiment.

FIG. 19 is a cross-sectional view (3/6) illustrating the method for manufacturing a light emitting device of the second embodiment.

FIG. 20 is a cross-sectional view (4/6) illustrating the method for manufacturing a light emitting device of the second embodiment.

FIG. 21 is a cross-sectional view (5/6) illustrating the method for manufacturing a light emitting device of the second embodiment.

FIG. 22 is a cross-sectional view (6/6) illustrating the method for manufacturing a light emitting device of the second embodiment.

FIG. 23 is a cross-sectional view (1/4) illustrating a method for manufacturing a light emitting device of a modification of the second embodiment.

FIG. 24 is a cross-sectional view (2/4) illustrating the method for manufacturing a light emitting device of the modification of the second embodiment.

FIG. 25 is a cross-sectional view (3/4) illustrating the method for manufacturing a light emitting device of the modification of the second embodiment.

FIG. 26 is a cross-sectional view (4/4) illustrating the method for manufacturing a light emitting device of the modification of the second embodiment.

FIG. 27 is a cross-sectional view illustrating a method for manufacturing a light emitting device of another modification of the second embodiment.

### MODE FOR CARRYING OUT THE INVENTION

Hereinafter, embodiments of the present disclosure will be described with reference to the drawings.

### First Embodiment

### (1) Distance Measuring Device 101 of First Embodiment

### (1.1) Configuration of Distance Measuring Device 101

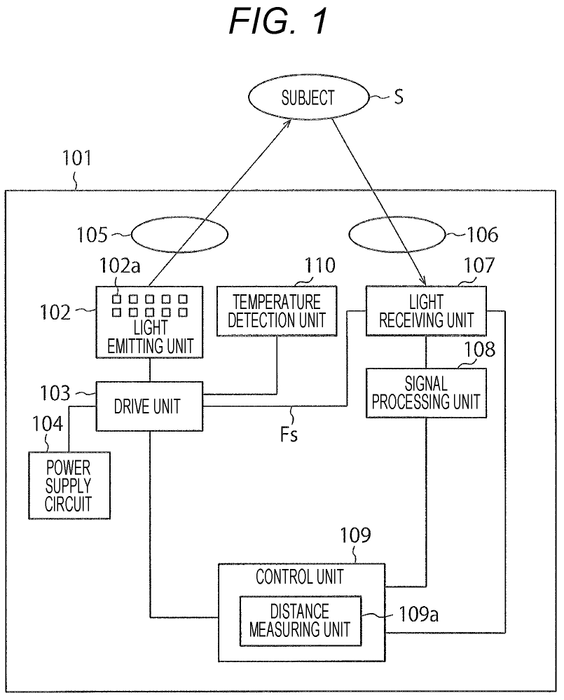

FIG. 1 is a block diagram illustrating a configuration example of a distance measuring device 101 of a first embodiment.

As illustrated in the drawing, the distance measuring device 101 includes a light emitting unit 102, a drive unit 103, a power supply circuit 104, a light-emitting side optical system 105, a light-receiving side optical system 106, a light receiving unit 107, a signal processing unit 108, a control unit 109, and a temperature detection unit 110.

The light emitting unit 102 emits light by a plurality of light sources. The light emitting unit 102 of the present example has a light emitting element 102a by a vertical cavity surface emitting laser (VCSEL) as each light source, and these light emitting elements 102a are arranged in a predetermined mode such as a matrix.

The drive unit 103 includes a power supply circuit for driving the light emitting unit 102.

The power supply circuit 104 generates a power supply voltage of the drive unit 103 on the basis of, for example, an input voltage from a battery or the like (not illustrated) provided in the distance measuring device 101. The drive unit 103 drives the light emitting unit 102 on the basis of the power supply voltage.

A subject S as a distance measurement target is irradiated with the light emitted from the light emitting unit 102 via the light-emitting side optical system 105. Then, the reflected light from the subject S of the light radiated in this manner is incident on the light receiving surface of the light receiving unit 107 via the light-receiving side optical system 106.

The light receiving unit 107 is, for example, a light receiving element such as a charge coupled device (CCD) sensor or a complementary metal oxide semiconductor (CMOS) sensor, receives reflected light from the subject S incident through the light-receiving side optical system 106 as described above, converts the reflected light into an electrical signal, and outputs the electrical signal.

The light receiving unit 107 executes, for example, correlated double sampling (CDS) processing, automatic gain control (AGC) processing, and the like on an electrical signal obtained by photoelectrically converting received light, and further performs analog/digital (A/D) conversion processing. Then, the signal as digital data is output to the signal processing unit 108 in the subsequent stage.

Furthermore, the light receiving unit 107 of the present example outputs a frame synchronization signal Fs to the drive unit 103. Thus, the drive unit 103 can cause the light emitting elements 102a in the light emitting unit 102 to emit light at timing corresponding to the frame period of the light receiving unit 107.

The signal processing unit 108 is configured as a signal processing processor by, for example, a digital signal processor (DSP) or the like. The signal processing unit 108 performs various types of signal processing on the digital signal input from the light receiving unit 107.

The control unit 109 includes, for example, a microcomputer including a central processing unit (CPU), a read only memory (ROM), a random access memory (RAM), and the like, or an information processing device such as a DSP, and performs control of the drive unit 103 for controlling light emission operation by the light emitting unit 102 and control related to light reception operation by the light receiving unit 107.

The control unit 109 has a function as a distance measuring unit 109a. The distance measuring unit 109a measures the distance to the subject S on the basis of a signal input via the signal processing unit 108 (that is, a signal obtained by receiving reflected light from the subject S). The distance measuring unit 109a of the present example measures the distance for each part of the subject S in order to enable identification of the three-dimensional shape of the subject S.

Here, a specific method for distance measurement in the distance measuring device 101 will be described again later.

The temperature detection unit 110 detects the temperature of the light emitting unit 102. As the temperature detection unit 110, for example, a configuration in which temperature detection is performed using a diode can be adopted.

In the present example, the information on the temperature detected by the temperature detection unit 110 is supplied to the drive unit 103, whereby the drive unit 103 can drive the light emitting unit 102 on the basis of the information on the temperature.

### (1.2) Distance Measuring Method

As a distance measuring method in the distance measuring device 101, for example, a distance measuring method by a structured light (STL) method or a time of flight (ToF) method can be adopted.

The STL method is a method for measuring a distance on the basis of an image of the subject S irradiated with light having a predetermined light/dark pattern such as a dot pattern or a lattice pattern.

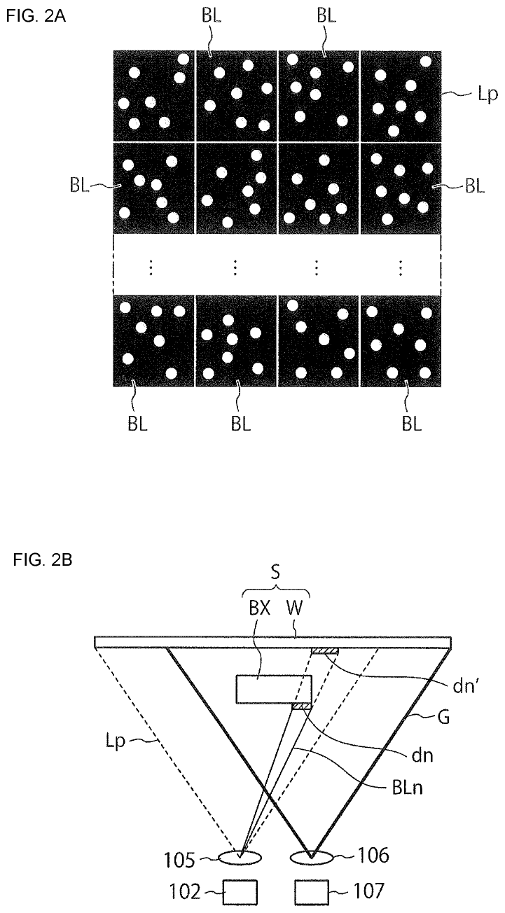

FIG. 2 is a diagram for explaining the STL method of the first embodiment.

In the STL method, for example, the subject S is irradiated with pattern light Lp by a dot pattern as illustrated in A of FIG. 2. The pattern light Lp is divided into a plurality of blocks BL, and different dot patterns are allocated to the respective blocks BL (the dot patterns do not overlap between the blocks B).

B of FIG. 2 is an explanatory diagram of the distance measurement principle of the STL method.

Here, an example in which a wall W and a box BX arranged in front of the wall W are the subject S, and the subject S is irradiated with the pattern light Lp is used. “G” in the drawing schematically represents the angle of view by the light receiving unit 107.

In addition, “BLn” in the drawing means light of a certain block BL in the pattern light Lp, and “dn” means a dot pattern of the block BLn projected on the light receiving image by the light receiving unit 107.

Here, in a case where the box BX in front of the wall W does not exist, the dot pattern of the block BLn is projected at the position of “dn′” in the drawing in the light receiving image. That is, the position at which the pattern of the block BLn is projected in the light receiving image is different between the case where the box BX exists and the case where the box BX does not exist, and specifically, the pattern distortion occurs.

The STL method is a method for obtaining the shape and depth of the subject S by using the fact that the pattern irradiated in this manner is distorted by the object shape of the subject S. Specifically, the STL method is a method for obtaining the shape and depth of the subject S from the way of the distortion of the pattern.

In the case of adopting the STL method, for example, an infrared (IR) light receiving unit by a global shutter method is used as the light receiving unit 107. Then, in the case of the STL method, the distance measuring unit 109a controls the drive unit 103 so that the light emitting unit 102 emits pattern light, detects the distortion of the pattern for the image signal obtained via the signal processing unit 108, and calculates the distance on the basis of the distortion of the pattern.

Subsequently, the ToF method is a method for measuring a distance to an object by detecting a flight time (time difference) of light emitted from the light emitting unit 102 until the light is reflected by the object and reaches the light receiving unit 107.

In a case where a so-called direct ToF (dTOF) method is adopted as the ToF method, a single photon avalanche diode (SPAD) is used as the light receiving unit 107, and the light emitting unit 102 is pulse-driven. In this case, the distance measuring unit 109a calculates a time difference between light emission and light reception for light emitted from the light emitting unit 102 and received by the light receiving unit 107 on the basis of a signal input via the signal processing unit 108, and calculates a distance to each unit of the subject S on the basis of the time difference and the speed of light.

Note that, in a case where a so-called indirect ToF (iTOF) method (phase difference method) is adopted as the ToF method, for example, a light receiving unit capable of receiving IR is used as the light receiving unit 107.

### (2) Light Emitting Device 1 of First Embodiment

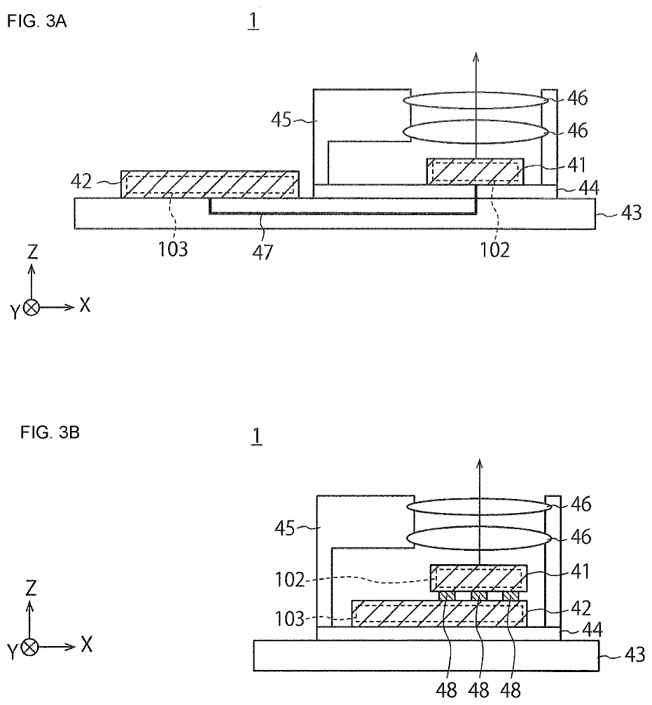

FIG. 3 is a cross-sectional view illustrating an example of a structure of a light emitting device 1 of the first embodiment. The light emitting device 1 of the present embodiment may be a part of the distance measuring device 101 or may be the distance measuring device 101 itself.

A of FIG. 3 illustrates a first example of the structure of the light emitting device 1 of the present embodiment. The light emitting device 1 of the present example includes an LD chip 41 including a light emitting unit 102, an LDD substrate 42 including a drive unit 103, a mounting substrate 43, a heat dissipation substrate 44, a correction lens holding unit 45, one or more correction lenses 46, and wiring 47.

A of FIG. 3 illustrates an X axis, a Y axis, and a Z axis perpendicular to each other. An X direction and a Y direction correspond to a lateral direction (horizontal direction), and a Z direction corresponds to a longitudinal direction (vertical direction). In addition, a +Z direction corresponds to an upward direction, and a −Z direction corresponds to a downward direction. The −Z direction may strictly match the gravity direction, or does not necessarily strictly match the gravity direction.

The LD chip 41 is arranged on the mounting substrate 43 with the heat dissipation substrate 44 interposed therebetween, and the LDD substrate 42 is also arranged on the mounting substrate 43. The mounting substrate 43 is, for example, a printed board. On the mounting substrate 43, the light receiving unit 107 and the signal processing unit 108 illustrated in FIG. 1 may further be arranged. The heat dissipation substrate 44 is, for example, a ceramic substrate such as an aluminum oxide substrate or an aluminum nitride substrate.

The correction lens holding unit 45 is arranged on the heat dissipation substrate 44 so as to surround the LD chip 41, and holds one or more of correction lenses 46 above the LD chip 41. These correction lenses 46 are included in the above-described light-emitting side optical system 105. The light emitted from the light emitting unit 102 in the LD chip 41 is corrected by these correction lenses 46 and then radiated to the subject S. A of FIG. 3 illustrates two correction lenses 46 held by the correction lens holding unit 45 as an example.

The wiring 47 is provided on the front surface, the back surface, the inside, or the like of the mounting substrate 43, and electrically connects the LD chip 41 and the LDD substrate 42. The wiring 47 is, for example, printed wiring provided on the front surface or the back surface of the mounting substrate 43 or via wiring penetrating the mounting substrate 43. The wiring 47 of the present embodiment further passes through the inside or the vicinity of the heat dissipation substrate 44.

B of FIG. 3 illustrates a second example of the structure of the light emitting device 1 of the present embodiment. The light emitting device 1 of the present example includes the same components as those of the light emitting device 1 of the first example, but includes bumps 48 instead of the wiring 47.

In B of FIG. 3, the LDD substrate 42 is arranged on the heat dissipation substrate 44, and the LD chip 41 is arranged on the LDD substrate 42. By arranging the LD chip 41 on the LDD substrate 42 in this manner, the size of the mounting substrate 43 can be reduced as compared with the case of the first example. In B of FIG. 3, the LD chip 41 is arranged on the LDD substrate 42 with the bumps 48 interposed therebetween, and is electrically connected to the LDD substrate 42 by the bumps 48.

Hereinafter, the light emitting device 1 of the present embodiment will be described as having the structure of the second example illustrated in B of FIG. 3. However, the following description is also applicable to the light emitting device 1 having the structure of the first example except for the description of the structure specific to the second example.

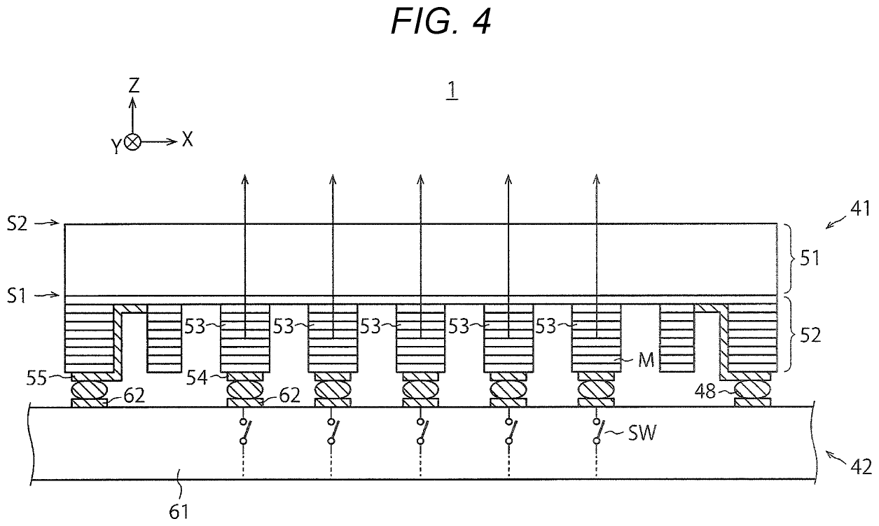

FIG. 4 is a cross-sectional view illustrating a structure of the light emitting device 1 illustrated in B of FIG. 3.

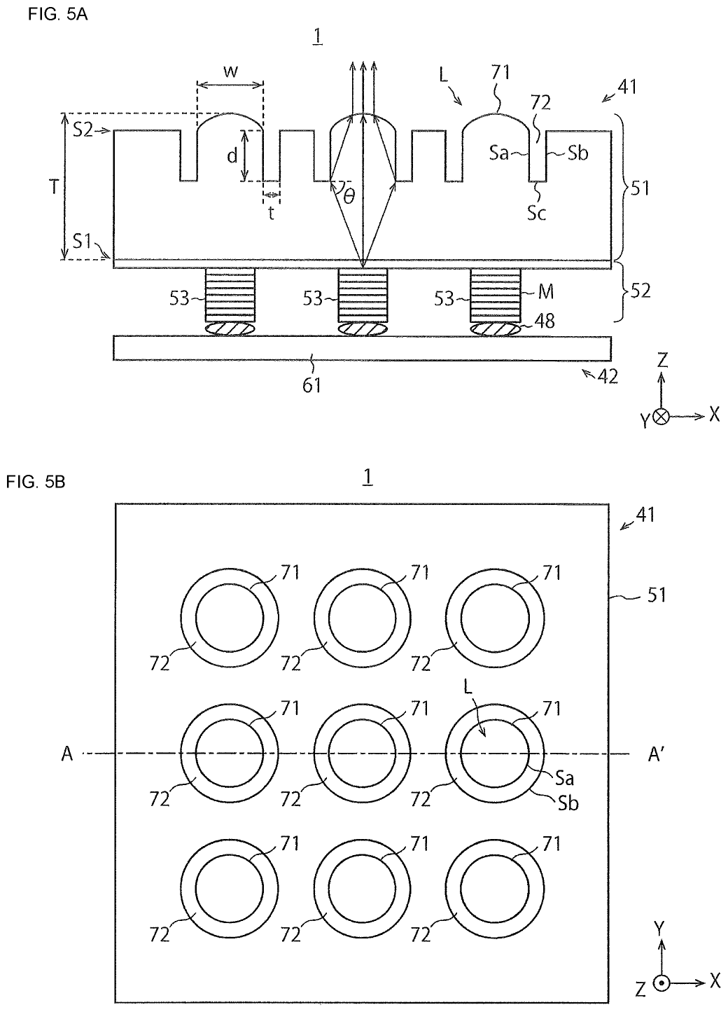

FIG. 4 illustrates cross sections of the LD chip 41 and the LDD substrate 42 in the light emitting device 1. As illustrated in FIG. 4, the LD chip 41 includes a substrate 51, a laminated film 52, a plurality of light emitting elements 53, a plurality of anode electrodes 54, and a plurality of cathode electrodes 55, and the LDD substrate 42 includes a substrate 61 and a plurality of connection pads 62. The light emitting element 53 illustrated in FIG. 4 is a specific example of the light emitting element 102a described above. Note that, in FIG. 4, illustration of a lens 71 and a groove 72 to be described later is omitted (see FIG. 5).

The substrate 51 is, for example, a semiconductor substrate such as a gallium arsenide (GaAs) substrate. FIG. 4 illustrates a front surface S1 of the substrate 51 facing the −Z direction and a back surface S2 of the substrate 51 facing the +Z direction. The front surface S1 and the back surface S2 illustrated in FIG. 4 are perpendicular to the Z direction. The front surface S1 is an example of a first surface of the present disclosure, and the back surface S2 is an example of a second surface of the present disclosure.

The laminated film 52 includes a plurality of layers laminated on the front surface S1 of the substrate 51. Examples of these layers include an n-type semiconductor layer, an active layer, a p-type semiconductor layer, a light reflecting layer, and an insulating layer having a light emission window. The laminated film 52 includes a plurality of mesa portions M protruding in the −Z direction. Parts of these mesa portions M are the plurality of light emitting elements 53.

The light emitting elements 53 are provided on the front surface S1 side of the substrate 51 as parts of the laminated film 52. The light emitting elements 53 of the present embodiment have a VCSEL structure and emit light in the +Z direction. As illustrated in FIG. 4, light emitted from the light emitting elements 53 is transmitted inside the substrate 51 from the front surface S1 to the back surface S2, and is incident on the above-described correction lenses 46 (FIG. 3) from the substrate 51. Thus, the LD chip 41 of the present embodiment is a back-side emission type VCSEL chip.

The anode electrodes 54 are formed on lower surfaces of the light emitting elements 53. The cathode electrodes 55 are formed on lower surfaces of the mesa portions M other than the light emitting elements 53, and extend up to a lower surface of the laminated film 52 that exists between the mesa portions M. Each light emitting element 53 emits light when a current flows between the corresponding anode electrode 54 and the corresponding cathode electrode 55.

As described above, the LD chip 41 is arranged on the LDD substrate 42 with the bumps 48 interposed therebetween, and is electrically connected to the LDD substrate 42 by the bumps 48. Specifically, the connection pads 62 are formed on the substrate 61 included in the LDD substrate 42, and the mesa portions M are arranged on the connection pads 62 with the bumps 48 interposed therebetween. Each mesa portion M is arranged on the bump 48 via the anode electrode 54 or the cathode electrode 55. The substrate 61 is, for example, a semiconductor substrate such as a silicon (Si) substrate.

The LDD substrate 42 includes the drive unit 103 that drives the light emitting unit 102. FIG. 4 schematically illustrates a plurality of switches SW included in the drive unit 103. Each switch SW is electrically connected to the corresponding light emitting element 53 via the bump 48. The drive unit 103 of the present embodiment can control (turn on and off) these switches SW for each switch SW. Therefore, the drive unit 103 can drive the plurality of light emitting elements 53 for every light emitting element 53. As a result, it is possible to precisely control the light emitted from the light emitting unit 102, for example, by causing only the light emitting elements 53 necessary for distance measurement to emit light. Such individual control of the light emitting elements 53 can be implemented by arranging the LDD substrate 42 below the LD chip 41, so that each light emitting element 53 is easily electrically connected to the corresponding switch SW.

FIG. 5 is a cross-sectional view and a plan view illustrating a structure of the light emitting device 1 of the first embodiment.

A of FIG. 5 illustrates cross sections of the LD chip 41 and the LDD substrate 42 in the light emitting device 1. As described above, the LD chip 41 includes the substrate 51, the laminated film 52, the plurality of light emitting elements 53, the plurality of anode electrodes 54, and the plurality of cathode electrodes 55, and the LDD substrate 42 includes the substrate 61 and the plurality of connection pads 62. However, in A of FIG. 5, illustration of the anode electrodes 54, the cathode electrodes 55, and the connection pads 62 is omitted.

As illustrated in A of FIG. 5, the LD chip 41 of the present embodiment includes the plurality of light emitting elements 53 on the front surface S1 side of the substrate 51, and a plurality of lenses 71 and a plurality of grooves 72 on the back surface S2 side of the substrate 51. B of FIG. 5 illustrates a layout of the lens 71 and the grooves 72 provided on the back surface S2 side of the substrate 51. A of FIG. 5 illustrates a cross section taken along line A-A′ illustrated in B of FIG. 5.

Hereinafter, details of the lenses 71 and the grooves 72 of the present embodiment will be described with reference to A of FIG. 5. In this description, B of FIG. 5 will also be referred to as appropriate.

Similarly to the light emitting elements 53, the lenses 71 are arranged in a two-dimensional array. The lenses 71 of the present embodiment correspond to the light emitting elements 53 on a one-to-one basis, and each lens 71 is arranged in the +Z direction of one light emitting element 53. The lenses 71 of the present embodiment are arranged in a square lattice pattern in B of FIG. 5, but may be arranged in other layouts.

Furthermore, as illustrated in A of FIG. 5, the lenses 71 of the present embodiment are provided as parts of the substrate 51 on the back surface S2 of the substrate 51. Specifically, the lenses 71 of the present embodiment are convex lenses, and are formed as parts of the substrate 51 by etching processing of the back surface S2 of the substrate 51 into convex shapes. According to the present embodiment, by forming the lenses 71 by etching processing of the substrate 51, the lenses 71 can be easily formed. Note that the lens 71 of the present embodiment may be other than a convex lens, and may be, for example, a concave lens, a binary lens, a Fresnel lens, or the like.

The groove 72 is provided between the lenses 71 in the substrate 51. As illustrated in B of FIG. 5, the groove 72 of the present embodiment corresponds to the lens 71 on a one-to-one basis, and each groove 72 has a shape surrounding one lens 71. Each groove 72 of the present embodiment has an annular shape in plan view, and annularly surrounds one lens 71. Each groove 72 is filled with air (air gap) in the present embodiment, but may be filled with some solid material, for example, an insulator such as quartz.

Here, the shape of each groove 72 will be described using the groove 72 surrounding the lens 71 indicated by reference sign L as an example. The lens 71 denoted by reference sign L will be referred to as a “lens L”. The lens L is an example of the first lens of the present disclosure, and the groove 72 surrounding the lens L is an example of the first groove of the present disclosure. Furthermore, the lens 71 other than the lens L is an example of a second lens of the present disclosure, and the groove 72 surrounding the lens 71 other than the lens L is an example of a second groove of the present disclosure. The following description is also applied to the lens 71 other than the lens L and the groove 72 surrounding the lens 71 other than the lens L.

The groove 72 surrounding the lens L has a side surface Sa on the lens L side, a side surface Sb on an opposite side to the lens L, and a bottom surface Sc between the side surface Sa and the side surface Sb. In the present embodiment, the cross-sectional shape of the groove 72 is rectangular as illustrated in A of FIG. 5 (rectangular groove), specifically, oblong. Therefore, the side surface Sa of the present embodiment is parallel to the Z direction, and the inclination angle of the side surface Sa with respect to the front surface S1 and the back surface S2 of the substrate 51 is 90 degrees. Similarly, the side surface Sb of the present embodiment is parallel to the Z direction, and the inclination angle of the side surface Sb with respect to the front surface S1 and the back surface S2 of the substrate 51 is 90 degrees. On the other hand, the bottom surface Sc of the present embodiment is perpendicular to the Z direction. The side surface Sa is an example of a first side surface of the present disclosure, and the side surface Sb is an example of a second side surface of the present disclosure.

Note that the inclination angle of the side surface Sa with respect to the front surface S1 and the back surface S2 of the substrate 51 may be other than 90 degrees, and may be, for example, 80 degrees or more and 100 degrees or less. Similarly, the inclination angle of the side surface Sb with respect to the front surface S1 or the back surface S2 of the substrate 51 may be other than 90 degrees, and may be, for example, 80 degrees or more and 100 degrees or less. In addition, the cross-sectional shapes of the side surface Sa, the side surface Sb, and the bottom surface Sc may be curved lines instead of straight lines. Further, the groove 72 surrounding the lens L may have only the side surface Sa and the side surface Sb instead of having the side surface Sa, the side surface Sb, and the bottom surface Sc. An example of such a groove 72 will be described later.

The substrate 51 of the present embodiment includes a plurality of grooves 72, and these grooves 72 are separated from each other in the substrate 51 as illustrated in B of FIG. 5. For example, the groove 72 surrounding the lens L is not connected to the other grooves 72 in the substrate 51. On the other hand, these grooves 72 may be connected to each other in the substrate 51. An example of such a groove 72 will be described later.

The light emitted from the plurality of light emitting elements 53 described above is transmitted through the substrate 51 from the front surface S1 to the back surface S2 of the substrate 51, and enters the plurality of lenses 71 described above. In the present embodiment, the light emitted from each light emitting element 53 is incident on one corresponding lens 71. As a result, the light emitted from the plurality of light emitting elements 53 described above can be molded for each lens 71. The light having passed through the plurality of lenses 71 described above passes through the correction lenses 46 (FIG. 3) and is radiated to the subject S (FIG. 1).

In A of FIG. 5, an optical path along which light emitted from one light emitting element 53 enters the corresponding lens 71 is indicated by arrows. In A of FIG. 5, the light emitted from the light emitting element 53 is incident on the side surface of the groove 72, reflected by the side surface of the groove 72, and incident on the lens 71. Similarly to the above-described side surface Sa, the side surface is provided on the lens 71 side in the groove 72.

A of FIG. 5 further illustrates a minimum incident angle θ of light incident on this side surface. This light is incident on a boundary portion between the side surface and the bottom surface of the groove 72. The groove 72 of the present embodiment has a shape in which the minimum incident angle θ is equal to or larger than the critical angle of total reflection on the side surface of the groove 72. Therefore, the light incident on the side surface of the groove 72 of the present embodiment is totally reflected by the side surface of the groove 72 regardless of where the light is incident on the side surface of the groove 72. This makes it possible to suppress this light from coming out of the substrate 51 from the side surface of the groove 72.

In the present embodiment, since the inclination angle of the side surface of the groove 72 is 90 degrees, it is easy to set the minimum incident angle θ to a large value, and it is easy to set the minimum incident angle θ to a critical angle or more. Therefore, according to the present embodiment, the groove 72 in which total reflection occurs can be easily realized. As a result, it is possible to improve light utilization efficiency and to suppress generation of stray light. It is easy to set the minimum incident angle θ to be equal to or larger than the critical angle even in a case where the inclination angle of the side surface of the groove 72 is 80 degrees or more and 100 degrees or less.

A of FIG. 5 illustrates a thickness T of the substrate 51, a width (diameter) w of the lens 71, a depth d of the groove 72, and a width t of the groove 72. Details of these dimensions will be described below.

The thickness T of the substrate 51 is, for example, 50 to 150 μm. The thickness T of the substrate 51 of the present embodiment is set to about 100 μm. In a case where the refractive index of the substrate 51 is represented by n1, the refractive index of the material filling the groove 72 is represented by n2, and the critical angle of total reflection on the side surface of the groove 72 is represented by θc, the critical angle θc is given by the expression of θc=sin⁻¹ (n2/n1). The substrate 51 of the present embodiment is a GaAs substrate, and the refractive index of GaAs is 3.6. In addition, the material filling the groove 72 of the present embodiment is air, and the refractive index of the air is 1. In this case, the critical angle θc is 17 degrees. On the other hand, in a case where the substrate 51 is a GaAs substrate (n1=3.6) and the material filling the groove 72 is quartz (n2=1.45), the critical angle θ c is 23.8 degrees.

The width w of the lens 71 is, for example, 10 to 30 μm. The width w of the lens 71 may be the same for all the lenses 71 or may be different for each lens 71. The width w of the lens 71 of the present embodiment is set to about 20 μm.

The depth d of the groove 72 is desirably set in consideration of, for example, the thickness T of the substrate 51 and the radiation angle of the light emitting element 53. The radiation angle of the light emitting element 53 is the maximum inclination angle of the light emitted from the light emitting element 53. In a case where the radiation angle of the light emitting element 53 is represented by a, the light emitted from the light emitting element 53 propagates in a direction inclined by an angle α at the maximum with respect to the +Z direction. When this light is incident on the bottom surface Sc of the groove 72 while propagating from the light emitting element 53 to the corresponding lens L, the light is reflected by the bottom surface Sc of the groove 72 and becomes return light. On the other hand, if this light is incident on the side surface Sa of the groove 72 while propagating from the light emitting element 53 to the corresponding lens L, generation of return light can be suppressed. Therefore, the depth d of the groove 72 of the present embodiment is desirably set sufficiently large so that the light emitted from the light emitting element 53 does not enter the bottom surface Sc of the groove 72. This can be realized by setting the depth d of the groove 72 sufficiently large so that the light propagating in the direction inclined by the angle α with respect to the +Z direction does not enter the bottom surface Sc of the groove 72.

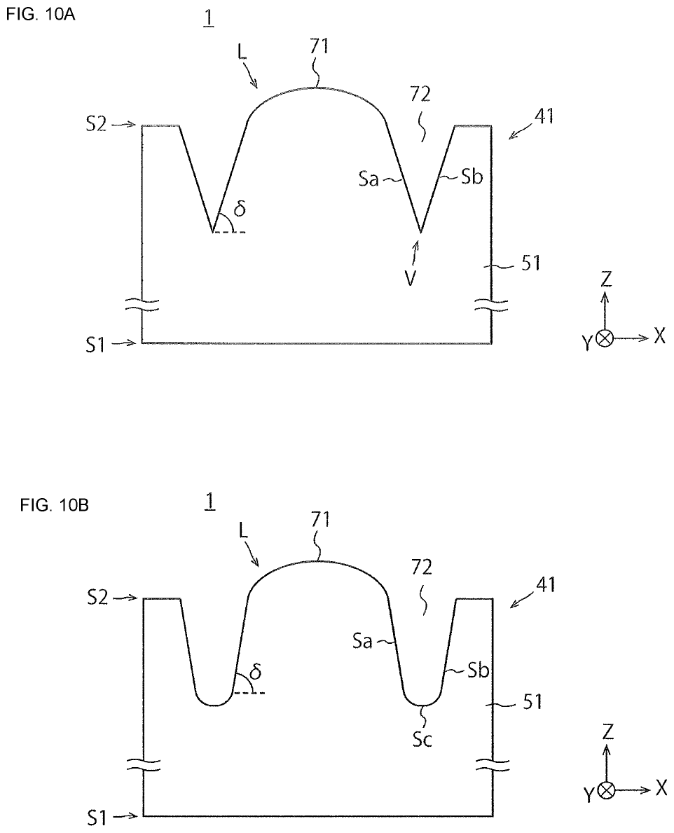

The setting of the depth d of the groove 72 as described above is also applicable to a case where the cross-sectional shape of the groove 72 is a shape other than a rectangle. In this case, the depth d of the groove 72 is desirably set sufficiently large so that the light emitted from the light emitting element 53 does not enter the deepest portion of the groove surface of the groove 72. The groove surface is a surface (for example, a side surface or a bottom surface) forming the groove 72. The deepest portion is the portion deepest in the surface forming the groove 72. For example, the deepest portion of the groove surface of the groove 72 surrounding the lens L illustrated in A of FIG. 5 is the bottom surface Sc of the groove 72. On the other hand, in a case where the cross-sectional shape of the groove 72 is V-shaped, the deepest portion is a V-shaped tip (see reference sign V illustrated in A of FIG. 10).

The width t of the groove 72 is desirably set in consideration of, for example, the wavelength of the light emitted from the light emitting element 53. In a case where the wavelength of the light emitted from the light emitting element 53 is represented by A, the width t of the groove 72 is desirably set to the wavelength λ or more. As a result, for example, by suppressing occurrence of a photon tunneling phenomenon, it is possible to suppress transmission of this light through the groove 72. Further, the width t of the groove 72 is preferably set to 2 times or more the wavelength λ, and more preferably set to 3 times or more the wavelength λ.

Note that, as described above, the groove 72 of the present embodiment may be filled with air or may be filled with an insulator. Examples of the insulator include the above-described quartz and metal oxides such as Ta₂O₅, Nb₂O₅, and TiO₂ (Ta represents tantalum, Nb represents niobium, and Ti represents titanium). The refractive index of quartz is 1.45, and the refractive index of such a metal oxide is about 2.3. Since it is desirable that the refractive index of the insulator embedded in the groove 72 is low, the refractive index of the insulator is desirably set to, for example, 2.3 or less. Embedding such a metal oxide film in the groove 72 has an advantage that, for example, a light shielding property in the groove 72 can be improved and generation of stray light can be effectively suppressed.

In addition, the groove 72 of the present embodiment may have a shape that totally reflects most of the light incident on the side surface of the groove 72 instead of having a shape that totally reflects all of the light incident on the side surface of the groove 72. This makes it possible to obtain an effect similar to the effect obtained by total reflection of all light. Similarly, the groove 72 of the present embodiment may have a shape in which all the light incident on the side surface of the groove 72 is totally reflected or reflected to an extent close to total reflection. This makes it possible to obtain an effect similar to the effect obtained by total reflection of all light.

Further, as described above, the groove 72 of the present embodiment has the side surface parallel to the Z direction (vertical side wall). In the present embodiment, since the light is totally reflected by such a side surface, reflected light having good symmetry can be obtained. Therefore, a fraction of light in the lateral direction can be stored with respect to the optical axis parallel to the Z direction, and the collimation function of the lens 71 can be suitably exhibited.

### (3) Light Emitting Device 1 of Comparative Example of First Embodiment

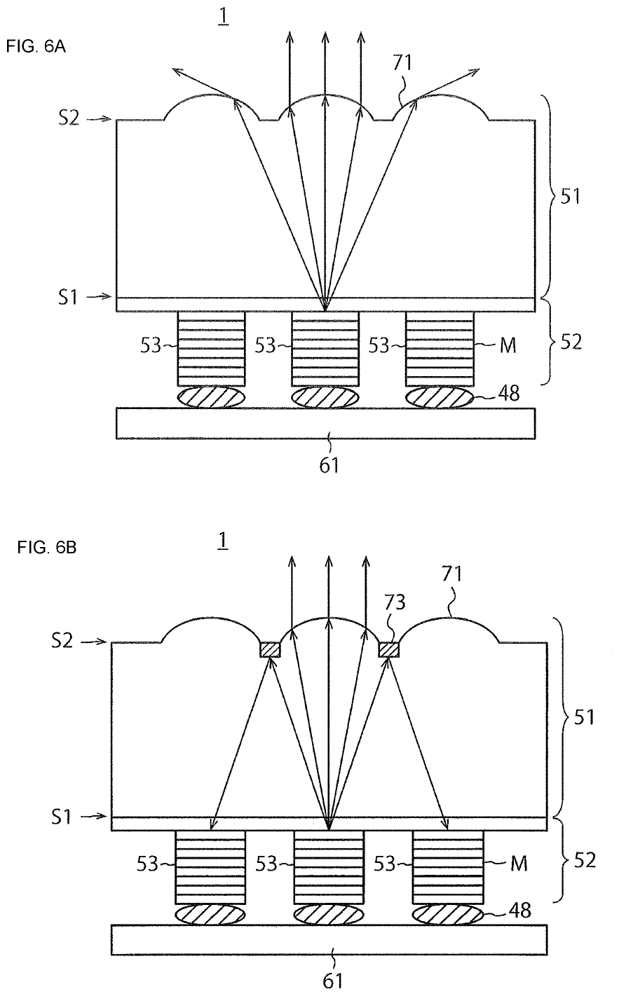

FIG. 6 is a cross-sectional view illustrating a structure of a light emitting device 1 of a comparative example of the first embodiment.

A of FIG. 6 illustrates a structure of a light emitting device 1 of a first comparative example of the first embodiment. The light emitting device 1 of the present comparative example has a structure in which the groove 72 is removed from the light emitting device 1 illustrated in A of FIG. 5. In A of FIG. 6, the light emitted from the light emitting element 53 at the center is incident not only on the lens 71 at the center but also on the right and left lenses 71, and crosstalk occurs. As described above, in the light emitting device 1 of the present comparative example, stray light is generated. Since the stray light does not correctly contribute to the distance measurement by the distance measuring device 101, the performance of the distance measurement may be deteriorated.

B of FIG. 6 illustrates a structure of a light emitting device 1 of a second comparative example of the first embodiment. The light emitting device 1 of the present comparative example has a structure in which the grooves 72 of the light emitting device 1 illustrated in A of FIG. 5 are replaced with light-shielding films 73. In B of FIG. 6, part of the light emitted from the light emitting element 53 at the center is reflected by the light-shielding film 73, and as a result, is not incident on the lens 71 at the center. As described above, in the light emitting device 1 of the present comparative example, the return light is generated. Since the return light does not contribute to the distance measurement by the distance measuring device 101 at all, the performance of the distance measurement may be deteriorated.

On the other hand, the light emitting device 1 of the present embodiment includes the groove 72 as described above between the lenses 71 in the substrate 51 (A of FIG. 5). Therefore, according to the present embodiment, generation of stray light and return light can be suppressed, and light emitted from the light emitting element 53 can be suitably incident on the lens 71. For example, stray light can be suppressed by totally reflecting the light emitted from the light emitting element 53 on the side surface of the groove 71. In addition, by setting the depth d of the groove 72 to a value at which the light emitted from the light emitting element 53 does not enter the bottom surface Sc of the groove 72, it is possible to suppress the return light.

### (4) Light Emitting Device 1 of Modification of First Embodiment

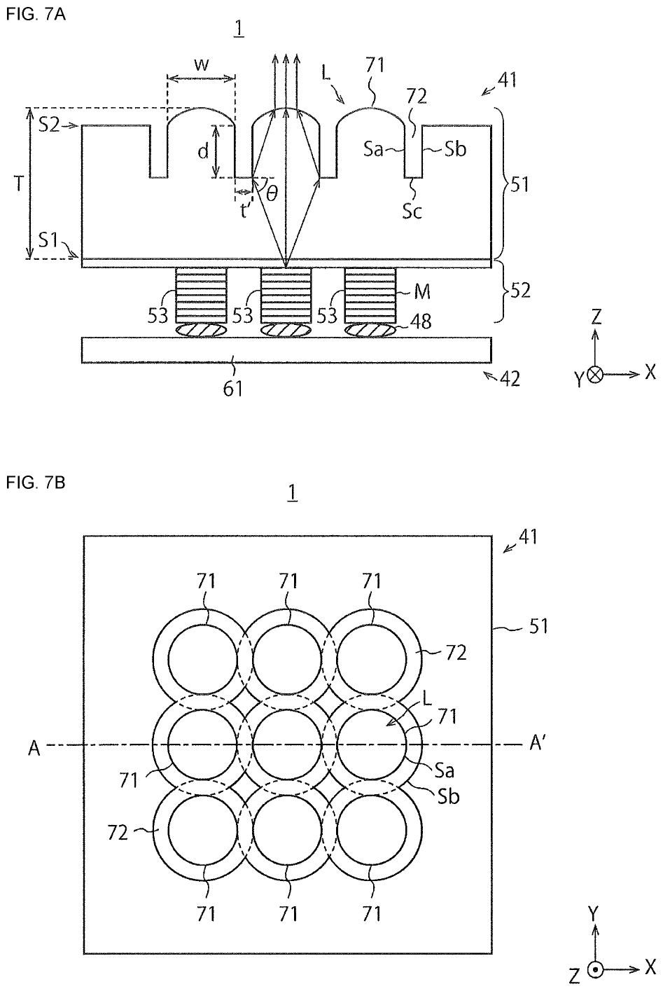

FIG. 7 is a cross-sectional view and a plan view illustrating a structure of a light emitting device 1 of a modification of the first embodiment.

A and B in FIG. 7 correspond to A and B in FIG. 5, respectively. A of FIG. 7 illustrates a cross section of the light emitting device 1 of the present modification. Similarly to the light emitting device 1 of the first embodiment, the light emitting device 1 of the present modification includes a plurality of lenses 71 and a plurality of grooves 72 annularly surrounding the lenses 71. B of FIG. 7 illustrates a layout of these lenses 71 and grooves 72. A of FIG. 7 illustrates a cross section taken along line A-A′ illustrated in B of FIG. 7.

In the present modification, these grooves 72 are connected to each other in the substrate 51 as illustrated in B of FIG. 7. In other words, these grooves 72 form one large groove in the substrate 51. This makes it possible to save a space for arranging these grooves 72. On the other hand, since the shapes of the grooves 72 separated from each other are generally simpler than the shapes of the grooves 72 connected to each other, it is desirable to separate these grooves 72 from each other in a case where it is desired to simplify the shapes of the grooves 72.

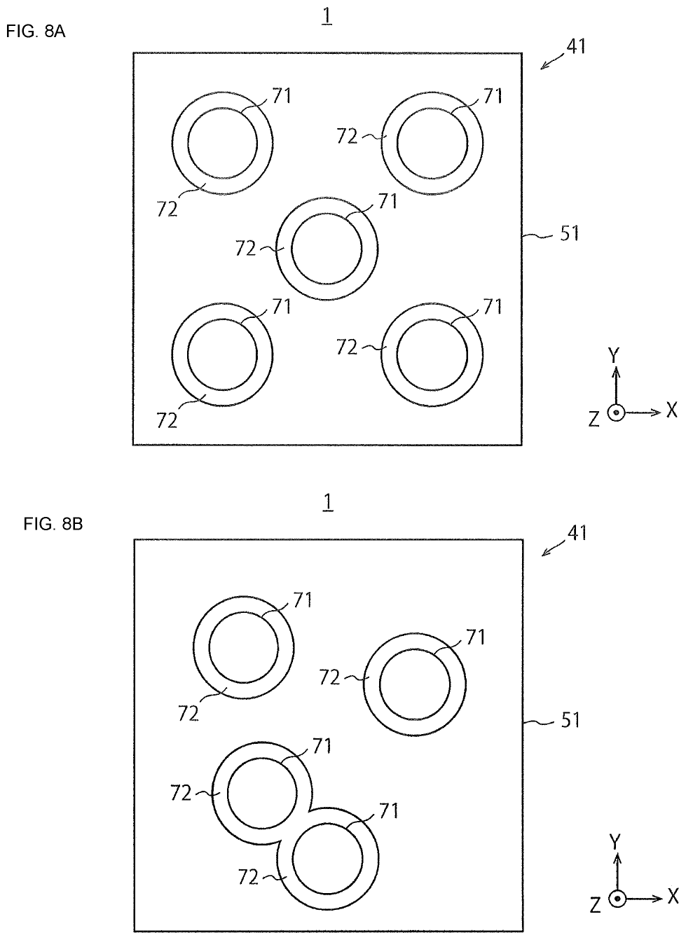

FIG. 8 is a plan view illustrating a structure of a light emitting device 1 of another modification of the first embodiment.

In the modification illustrated in A of FIG. 8, the lenses 71 are arranged in a square lattice pattern. However, while the square lattice illustrated in A of FIG. 5 and A of FIG. 7 is formed by a plurality of first straight lines parallel to the X direction and a plurality of second straight lines parallel to the Y direction, the square lattice illustrated in A of FIG. 8 is formed by a plurality of first straight lines non-parallel to the X direction and the Y direction and a plurality of second straight lines parallel to the X direction and the Y direction. In A of FIG. 8, the first straight lines extend in the +45 degree direction, and the second straight lines extend in the −45 degree direction. In this manner, these lenses 71 may be arranged in any lattice shape.

In the modification illustrated in B of FIG. 8, the lenses 71 are irregularly arranged. The light emitting device 1 of the present modification includes both the grooves 72 connected to each other and the grooves 72 separated from each other. In this manner, these lenses 71 may be arranged regularly or irregularly.

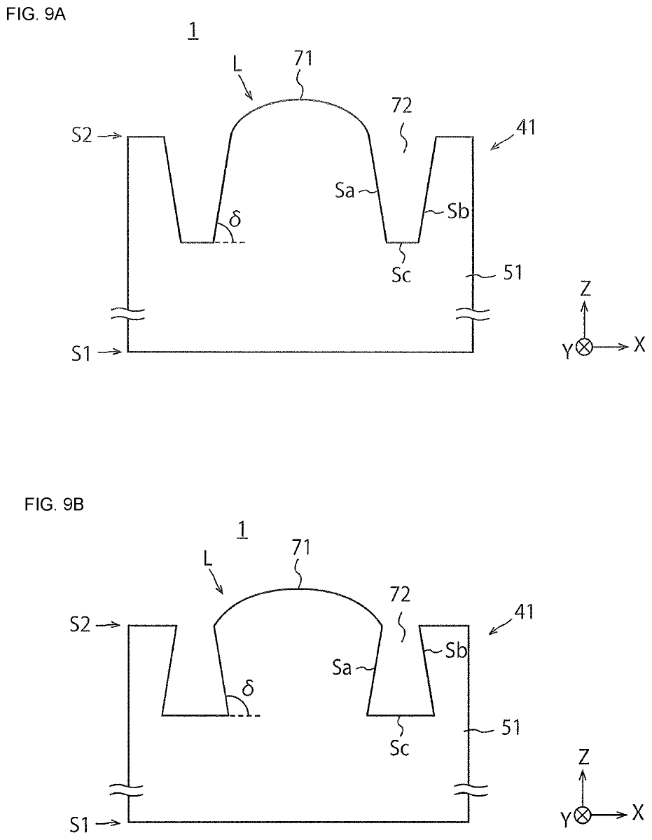

FIG. 9 is a cross-sectional view illustrating a structure of a light emitting device 1 of another modification of the first embodiment.

In the modification illustrated in A of FIG. 9, the groove 72 has the side surface Sa, the side surface Sb, and the bottom surface Sc. Reference sign δ illustrated in A of FIG. 9 indicates the inclination angle of the side surface Sa with respect to the front surface S1 or the back surface S2 of the substrate 51, and indicates the inclination angle of the side surface Sb with respect to the front surface S1 or the back surface S2 of the substrate 51. In the present modification, the inclination angle of the side surface Sa and the inclination angle of the side surface Sb are set to the same value. The inclination angle δ of the side surfaces Sa and Sb of the present modification is set to be smaller than 90 degrees. In this manner, the side surfaces Sa and Sb may not be parallel to the Z direction.

Therefore, the side surfaces Sa and Sb of the groove 72 of the present modification have a forward tapered shape, and the cross-sectional shape of the groove 72 is a trapezoid in which the upper base is longer than the lower base. The inclination angle δ of the side surfaces Sa and Sb of the present modification is desirably set to 80 degrees or more for the above-described reason.

Also in the modification illustrated in B of FIG. 9, the groove 72 has the side surface Sa, the side surface Sb, and the bottom surface Sc. Reference sign δ illustrated in B of FIG. 9 also indicates the inclination angle of the side surface Sa with respect to the front surface S1 or the back surface S2 of the substrate 51, and indicates the inclination angle of the side surface Sb with respect to the front surface S1 or the back surface S2 of the substrate 51. Also in the present modification, the inclination angle of the side surface Sa and the inclination angle of the side surface Sb are set to the same value. The inclination angle δ of the side surfaces Sa and Sb of the present modification is set to be larger than 90 degrees. In this manner, the side surfaces Sa and Sb may not be parallel to the Z direction.

Therefore, the side surfaces Sa and Sb of the groove 72 of the present modification have a reverse tapered shape, and the cross-sectional shape of the groove 72 is a trapezoid in which the upper base is shorter than the lower base. The inclination angle δ of the side surfaces Sa and Sb of the present modification is desirably set to 100 degrees or less for the above-described reason.

Note that the inclination angle δ illustrated in A and B of FIG. 9 is defined to be smaller than 90 degrees in a case where the side surfaces Sa and Sb of the groove 72 have a forward tapered shape, and to be larger than 90 degrees in a case where the side surfaces Sa and Sb of the groove 72 have a reverse tapered shape. Therefore, the inclination angle δ illustrated in A of FIG. 9 is smaller than 90 degrees, and the inclination angle δ illustrated in B of FIG. 9 is larger than 90 degrees.

FIG. 10 is a cross-sectional view illustrating a structure of a light emitting device 1 of another modification of the first embodiment.

In the modification illustrated in A of FIG. 10, the groove 72 has the side surface Sa and the side surface Sb, but does not have the bottom surface Sc. The cross-sectional shape of the groove 72 of the present modification is a V-shape (V-shaped groove), and the side surface Sa and the side surface Sb of the groove 72 are in contact with each other in the groove 72. A of FIG. 10 illustrates a boundary line V between the side surface Sa and the side surface Sb. The boundary line V is located at the tip of the V shape and is the deepest portion of the groove surface of the groove 72. The inclination angle δ of the side surfaces Sa and Sb of the present modification is desirably set to 80 degrees or more and less than 90 degrees.

In the modification illustrated in B of FIG. 10, the groove 72 has the side surface Sa, the side surface Sb, and the bottom surface Sc. However, the cross-sectional shape of the bottom surface Sc of the present modification is not a straight line but a curved line, specifically, a curved line having a downward convex shape. In the present modification, the lower end of the bottom surface Sc is the deepest portion of the groove surface of the groove 72. The inclination angle δ of the side surfaces Sa and Sb of the present modification is also desirably set to 80 degrees or more and less than 90 degrees. However, in a case where the side surfaces Sa and Sb of the groove 72 of the present modification are vertical side walls or reverse tapered side walls, the inclination angle δ of the side surfaces Sa and Sb may be set to 90 degrees or more and 100 degrees or less.

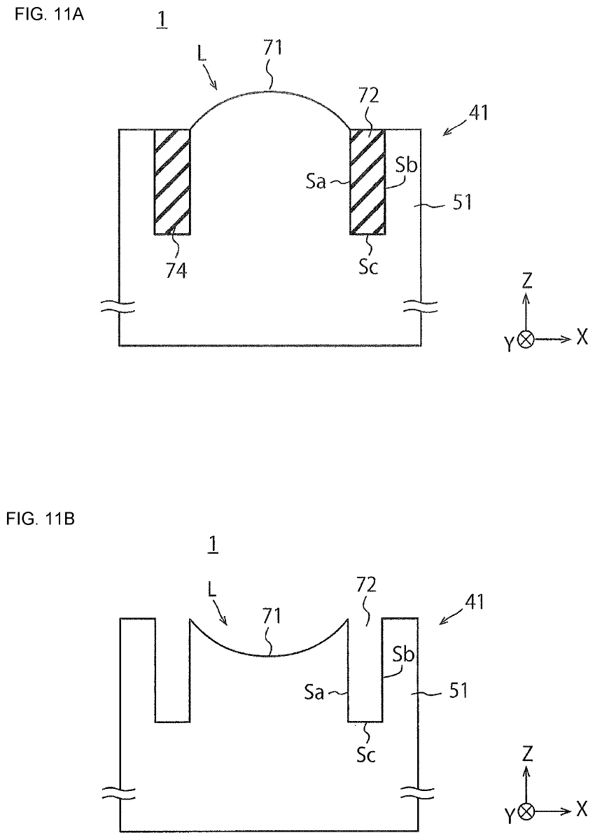

FIG. 11 is a cross-sectional view illustrating a structure of a light emitting device 1 of another modification of the first embodiment.

In the modification illustrated in A of FIG. 11, the light emitting device 1 further includes an insulating film 74 provided in the groove 72. The insulating film 74 is, for example, a quartz film, or a metal oxide film such as a Ta₂O₅ film, a Nb₂O₅ film, or a TiO₂ film. The insulating film 74 of the present modification covers the side surface Sa, the side surface Sb, and the bottom surface Sc of the groove 72 and fills the entire groove 72. As described above, the refractive index of the insulating film 74 is desirably 2.3 or less.

In the modification illustrated in B of FIG. 11, the lens 71 is not a convex lens but a concave lens. The lens 71 is formed as parts of the substrate 51 by etching processing of the back surface S2 of the substrate 51 into a concave shape. According to the present modification, similarly to the case where the lens 71 is a convex lens, the lens 71 is formed by etching processing of the substrate 51, so that the lens 71 can be easily formed.

Note that, in the light emitting device 1 of the present embodiment and the light emitting devices 1 of these modifications, the cross-sectional shape of each groove 72 is line-symmetric with respect to the Z axis. On the other hand, the cross-sectional shape of each groove 72 may not be line-symmetric with respect to the Z axis. For example, the inclination angle of the side surface Sb may be different from the inclination angle of the side surface Sa. This similarly applies to the cross-sectional shape of each lens 71.

Furthermore, in the light emitting device 1 of the present embodiment and the light emitting devices 1 of these modifications, the shape of each lens 71 in plan view is point-symmetric with respect to the Z axis. On the other hand, the shape of each lens 71 in plan view may not be point-symmetric with respect to the Z axis. For example, the shape of each lens 71 in plan view may be not circular but elliptical. This similarly applies to the shape of each groove 72 in plan view.

### (5) Method for Manufacturing for Light Emitting Device 1 of First Embodiment

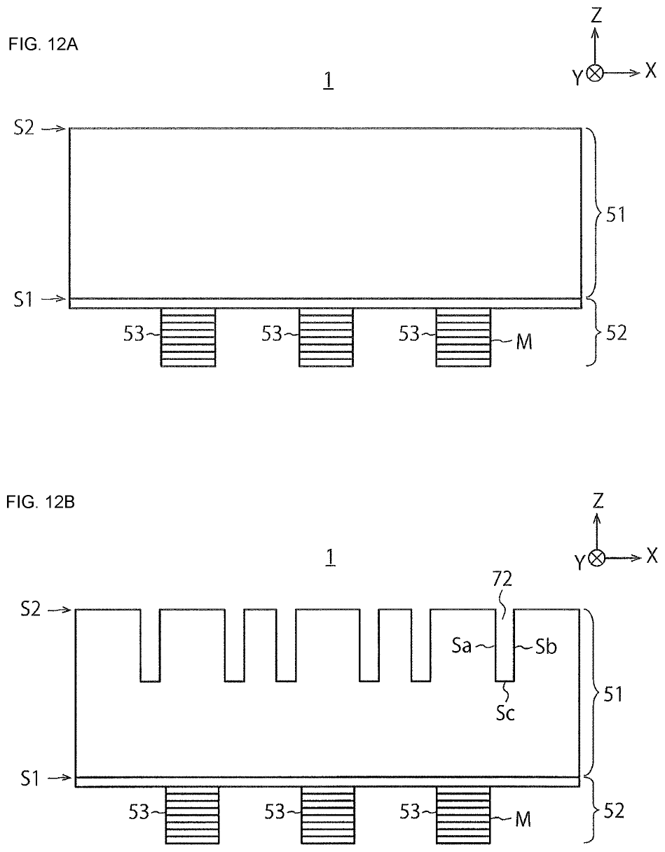

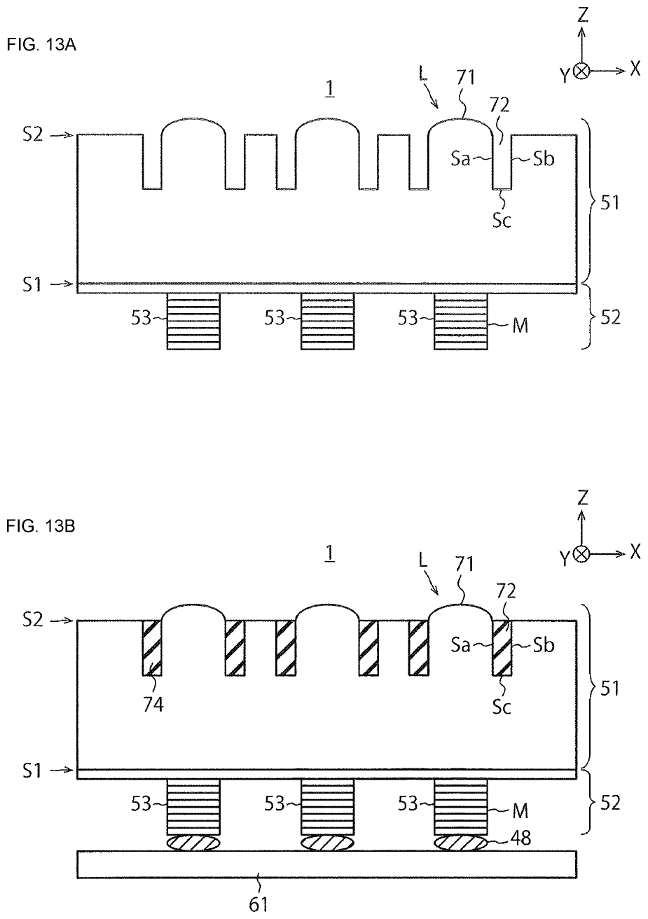

FIGS. 12 and 13 are cross-sectional views illustrating a method for manufacturing the light emitting device 1 of the first embodiment.

First, the laminated film 52 and the light emitting element 53 are formed on the surface S1 of the substrate 51 (A of FIG. 12). Next, the grooves 72 are formed on the back surface S2 of the substrate 51 (B of FIG. 12). The process in A of FIG. 12 is performed with the surface S1 of the substrate 51 facing upward. On the other hand, the process in B of FIG. 12 is performed with the back surface S2 of the substrate 51 facing upward.

The groove 72 of the present embodiment is formed by, for example, lithography and reactive ion etching (RIE). Each groove 72 is formed around the area where the corresponding lens 71 is to be formed. In addition, each groove 72 is formed to have the side surface Sa, the side surface Sb, and the bottom surface Sc described with reference to A and B of FIG. 5 and the like.

Next, the lens 71 is formed on the back surface S2 of the substrate 51 (A of FIG. 13). The lens 71 of the present embodiment is formed by, for example, lithography and RIE. Each lens 71 is formed inside the corresponding groove 72. As a result, a structure in which each lens 71 is surrounded by the corresponding groove 72 is realized. In this way, the light emitting device 1 illustrated in A and B of FIG. 5 is manufactured.

The process of B of FIG. 13 is performed when the light emitting device 1 illustrated in A of FIG. 11 is manufactured. In the process of B of FIG. 13, the insulating film 74 is formed on the entire back surface S2 of the substrate 51, and then the insulating film 74 outside the grooves 72 is removed by etching. As a result, the insulating film 74 is embedded in the grooves 72. In this way, the light emitting device 1 illustrated in A of FIG. 11 is manufactured.

Note that the process in A of FIG. 12, the process in B of FIG. 12, and the process in A of FIG. 13 may be performed in a different order. For example, these steps may be performed in the order of the step A in FIG. 12, the step A in FIG. 13, and the step B in FIG. 12. That is, the grooves 72 may be formed after the formation of the lenses 71.

Furthermore, the methods illustrated in A of FIG. 12 to A of FIG. 13 may be used to manufacture the light emitting device 1 of each modification of the present embodiment. For example, when the light emitting device 1 illustrated in B of FIG. 11 is manufactured, the concave lenses are formed in the process of A of FIG. 13. Further, when the light emitting device 1 illustrated in A of FIG. 10 is manufactured, the V-shaped grooves are formed in the process of B of FIG. 12.

As described above, the light emitting device 1 of the present embodiment includes the grooves 72 having the above-described shape. For example, the groove 72 of the present embodiment has the side surface Sa having an inclination angle of 80 degrees or more and 100 degrees or less. For example, the depth d of the groove 72 of the present embodiment is set to a value at which the light emitted from the light emitting element 53 does not enter the deepest portion of the groove surface of the groove 72. Therefore, according to the present embodiment, the light emitted from the light emitting element 53 can be suitably incident on the lens 71.

### Second Embodiment

### (1) Light Emitting Device 1 of Second Embodiment

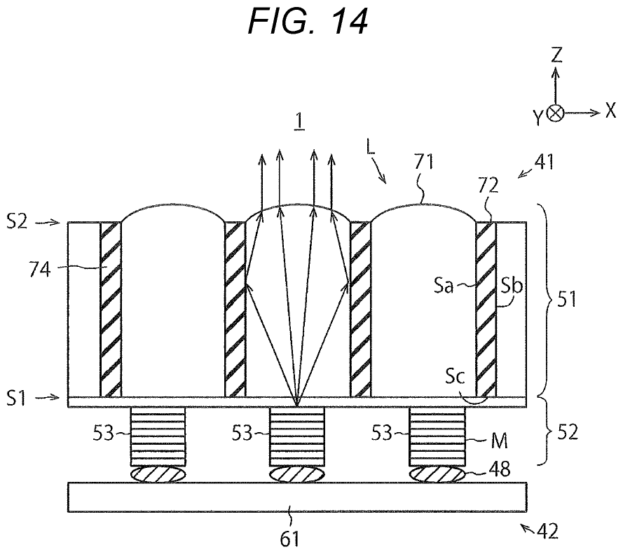

FIG. 14 is a cross-sectional view illustrating a structure of a light emitting device 1 of a second embodiment.

The light emitting device 1 of the present embodiment includes components similar to those of the light emitting device 1 of the first embodiment (see A of FIG. 5 and the like). However, the grooves 72 of the present embodiment are through grooves penetrating the substrate 51. The bottom surface Sc of the groove 72 is formed by the upper surface of the laminated film 52.

According to the present embodiment, the depth d (see A of FIG. 5 and the like) of the groove 72 can be easily increased. Therefore, the depth d of the groove 72 of the present embodiment is set to a value at which the light emitted from the light emitting element 53 is not incident on the bottom surface Sc of the groove 72. This makes it possible to effectively suppress generation of stray light and return light. Note that the groove 72 of the present embodiment may penetrate not only the substrate 51 but also a portion other than the mesa portion M in the laminated film 52.

The grooves 72 of the present embodiment penetrate the substrate 51 between the front surface S1 and the back surface S2 of the substrate 51. The grooves 72 of the present embodiment may be formed by etching the substrate 51 from the front surface S1 side of the substrate 51, or may be formed by etching the substrate 51 from the back surface S2 side of the substrate 51.

The light emitting device 1 of the present embodiment further includes the insulating film 74 provided in the groove 72, similarly to the light emitting device 1 illustrated in A of FIG. 11. As described above, the insulating film 74 is desirably formed of, for example, a material having a low refractive index. Furthermore, the insulating film 74 may be formed of a material having a low thermal expansion coefficient or elastic modulus. This makes it possible to suppress warpage and cracking of the substrate 51.

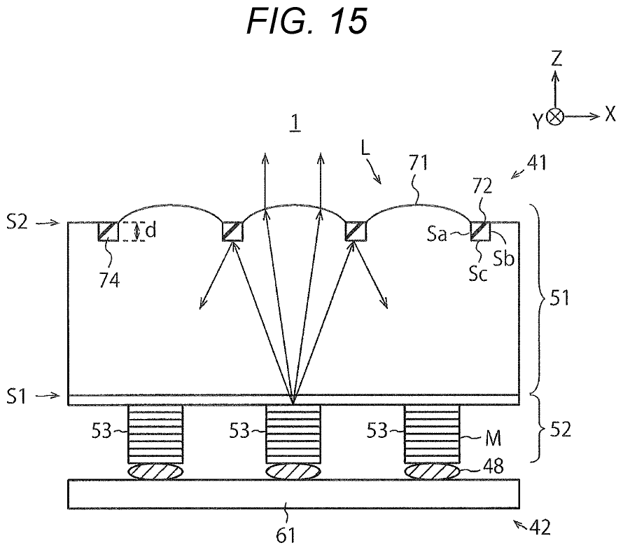

FIG. 15 is a cross-sectional view illustrating a structure of a light emitting device 1 of a comparative example of the second embodiment.

The light emitting device 1 of the present comparative example includes components similar to those of the light emitting device 1 of the second embodiment (see FIG. 14). However, the groove 72 of the present comparative example does not penetrate the substrate 51, and the depth d of the groove 72 of the present comparative example is set to be shallow. Therefore, in the present comparative example, stray light or return light may be generated. On the other hand, according to the present embodiment, generation of stray light and return light can be effectively suppressed.

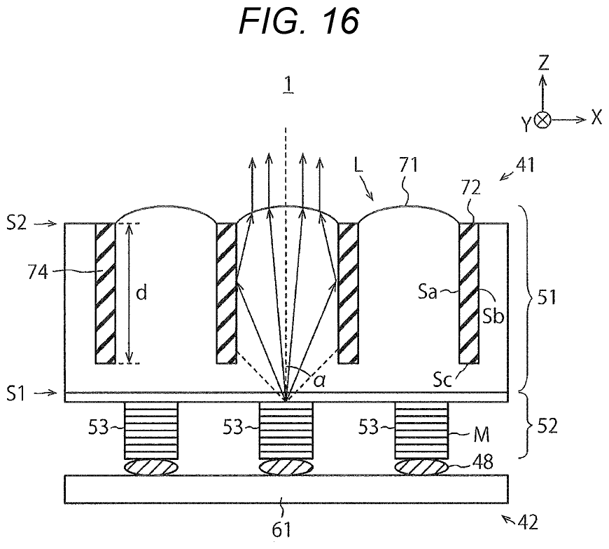

FIG. 16 is a cross-sectional view illustrating a structure of a light emitting device 1 of a modification of the second embodiment.

The light emitting device 1 of the present modification includes components similar to those of the light emitting device 1 of the comparative example of the second embodiment (see FIG. 15), and the groove 72 of the present modification does not penetrate the substrate 51. However, the depth d of the groove 72 of the present modification is set deep.

FIG. 16 illustrates the radiation angle α of the light emitting element 53. As described above, the radiation angle α of the light emitting element 53 is the maximum inclination angle of the light emitted from the light emitting element 53. Therefore, the light emitted from the light emitting element 53 propagates in a direction inclined at the maximum by the angle α with respect to the +Z direction. When the light is incident on the bottom surface of the groove 72 while propagating from the light emitting element 53 to the corresponding lens 71, the light is reflected by the bottom surface of the groove 72 and becomes return light. On the other hand, if this light is incident on the side surface of the groove 72 while propagating from the light emitting element 53 to the corresponding lens 71, generation of return light can be suppressed. Therefore, the depth d of the groove 72 of the present modification is desirably set sufficiently deep so that the light emitted from the light emitting element 53 does not enter the bottom surface of the groove 72. This can be realized by setting the depth d of the groove 72 sufficiently deep so that the light propagating in the direction inclined by the angle α with respect to the +Z direction does not enter the bottom surface of the groove 72.

The depth d of the groove 72 of the present modification is set deep as described above. Specifically, as illustrated in FIG. 16, the depth d of the groove 72 of the present modification is set to a value at which the light emitted from the light emitting element 53 does not enter the bottom surface of the groove 72. This makes it possible to effectively suppress generation of stray light and return light.

The light emitting device 1 of the present embodiment may be manufactured, for example, by a method illustrated in FIGS. 12 and 13, or may be manufactured by a method to be described later.

### (2) Method for Manufacturing Light Emitting Device 1 of Second Embodiment

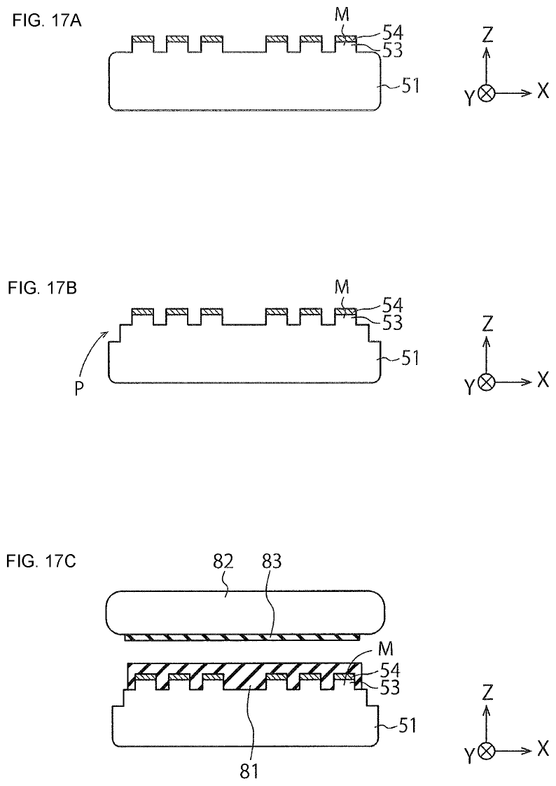

FIGS. 17 to 22 are cross-sectional views illustrating the method for manufacturing the light emitting device 1 of the second embodiment.

First, the laminated film 52, the plurality of light emitting elements 53, the plurality of anode electrodes 54, the plurality of cathode electrodes 55, and the like are formed on the upper surface of the substrate (wafer) 51 (A of FIG. 17). However, the laminated film 52 and the cathode electrode 55 are not illustrated. A of FIG. 17 further illustrates the plurality of mesa portions M described above. In A of FIG. 17, the light emitting element 53 and the anode electrode 54 are sequentially formed on the upper surface of the substrate 51. Note that the upper surface of the substrate 51 in A of FIG. 17 is the front surface S1 of the substrate 51.

Next, trimming processing of the edge portion of the substrate 51 is performed (B of FIG. 17). B of FIG. 17 illustrates a trimming portion P of the substrate 51. The width of the trimming portion P in the lateral direction is, for example, 1 to 5 mm. This trimming processing is performed to suppress chipping and cracking of the substrate 51 when the substrate 51 is thinned.

Next, an adhesive material 81 is applied to the upper surface of the substrate 51 so as to cover the mesa portions M and the like (C of FIG. 17). The adhesive material 81 may be an organic material or an inorganic material. The adhesive material 81 is used to temporarily bond the substrate 51 and a support substrate 82 in the present embodiment, but may be used to permanently bond the substrate 51 and the support substrate 82. In a case where the substrate 51 and the support substrate 82 are temporarily bonded by the adhesive material 81, a process of peeling the support substrate 82 from the substrate 51 is performed later. On the other hand, in a case where the substrate 51 and the support substrate 82 are permanently bonded by the adhesive material 81, a process of scraping the support substrate 82 from the substrate 51 is performed later.

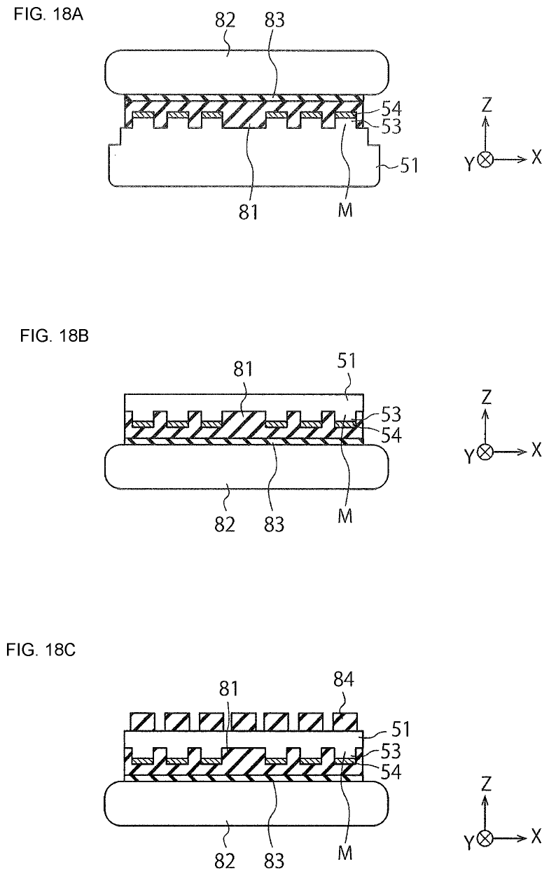

Next, a release layer 83 is applied to the support substrate 82 (C of FIG. 17), and the substrate 51 and the support substrate 82 are bonded via the adhesive material 81 and the release layer 83 (A of FIG. 18). In the present embodiment, a process of peeling the support substrate 82 from the substrate 51 by decomposing the release layer 83 with UV light (ultraviolet light) is performed later. The release layer 83 may be decomposed by heat instead of being decomposed by UV light. On the other hand, in a case where the adhesive material 81 includes the release layer 83, the release layer 83 may not be applied to the support substrate 82. In addition, the substrate 51 and the support substrate 82 of the present embodiment are bonded by one or more baking treatments at a bonding temperature of 80° C. and a curing temperature of 120 to 190° C.

The substrate 51 of the present embodiment is a GaAs substrate as described above. The support substrate 82 may be formed of any material, but is desirably formed of a material having a thermal expansion coefficient close to that of GaAs so that warpage does not occur after bonding to the substrate 51. In the present embodiment, since debonding is performed using UV light, the support substrate 82 is desirably a glass substrate that transmits UV light. The support substrate 82 of the present embodiment is, for example, a glass substrate having a transmittance of laser light having a wavelength of 355 nm of 80% or more and a thermal expansion coefficient of about 5 to 6 ppm/° C.

Next, after the substrate 51 and the support substrate 82 are turned upside down, the substrate 51 is thinned (B of FIG. 18). The substrate 51 is thinned by, for example, chemical mechanical polishing (CMP). Note that the upper surface of the substrate 51 in B of FIG. 18 is the back surface S2 of the substrate 51.

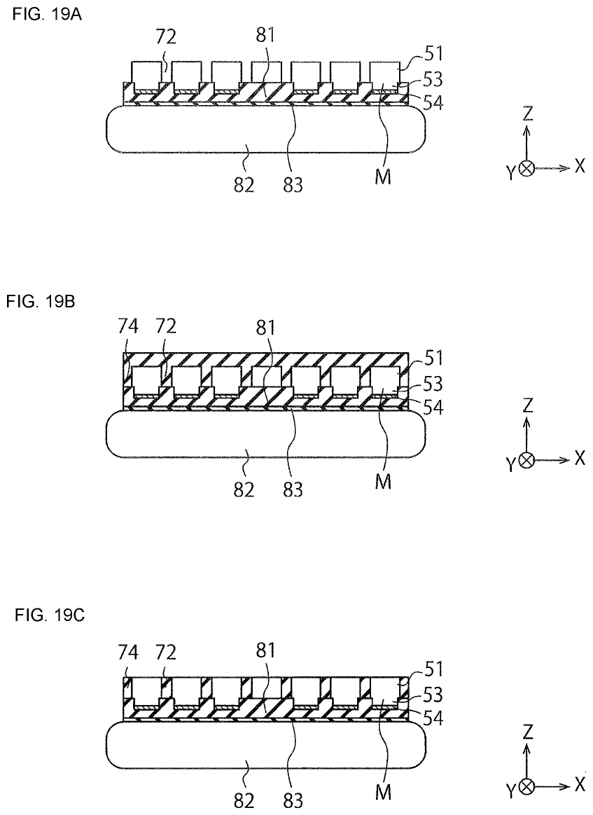

Next, a resist film 84 is formed on the substrate 51, and the resist film 84 is patterned (C of FIG. 18). Next, the grooves 72 are formed in the substrate 51 by dry etching using the resist film 84 as a mask (A of FIG. 19). In the present embodiment, the grooves 72 are formed so as to penetrate the substrate 51, but may be formed so as not to penetrate the substrate 51.

Next, the insulating film 74 is formed on the substrate 51 (B of FIG. 19), and the insulating film 74 outside the grooves 72 is removed by etching or CMP (C of FIG. 19). As a result, the insulating film 74 is embedded in the grooves 72. The insulating film 74 is, for example, a silicon oxide film, an aluminum oxide film, an organic film, or the like. The insulating film 74 is desirably formed of a material having a low refractive index, thermal expansion coefficient, or elastic modulus. The film thickness of the insulating film 74 is desirably, for example, 100 nm or more. The insulating film 74 can be formed by, for example, chemical vapor deposition (CVD), sputtering, molecular beam epitaxy (MBE), vapor deposition, spin coating, or the like.

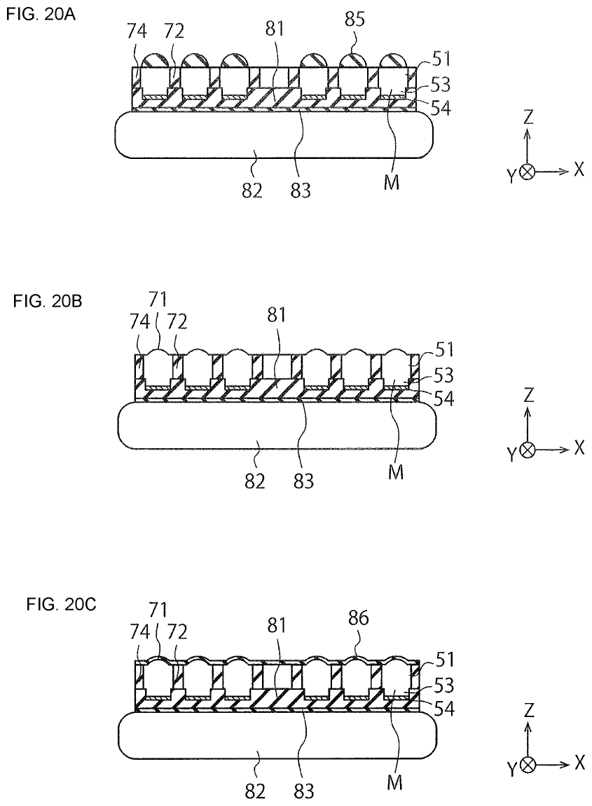

Next, a resist film 85 is formed on the substrate 51, the resist film 85 is patterned, and the patterned resist film 85 is reflowed by heat treatment (A of FIG. 20). As a result, the resist film 85 is processed into a shape similar to that of the lens 71.

Next, the lenses 71 are formed on the upper surface of the substrate 51 by dry etching using the resist film 85 as a mask (B of FIG. 20). In the present embodiment, the lenses 71 are formed as parts of the substrate 51 by processing the upper surface of the substrate 51.

Next, an antireflection film (AR film) 86 is formed on the substrate 51 (C of FIG. 20). As a result, the upper surfaces of the lenses 71 and the insulating film 74 are covered with the antireflection film 86. Note that, in a case where the antireflection film 86 is unnecessary, the process in C of FIG. 20 may be omitted.

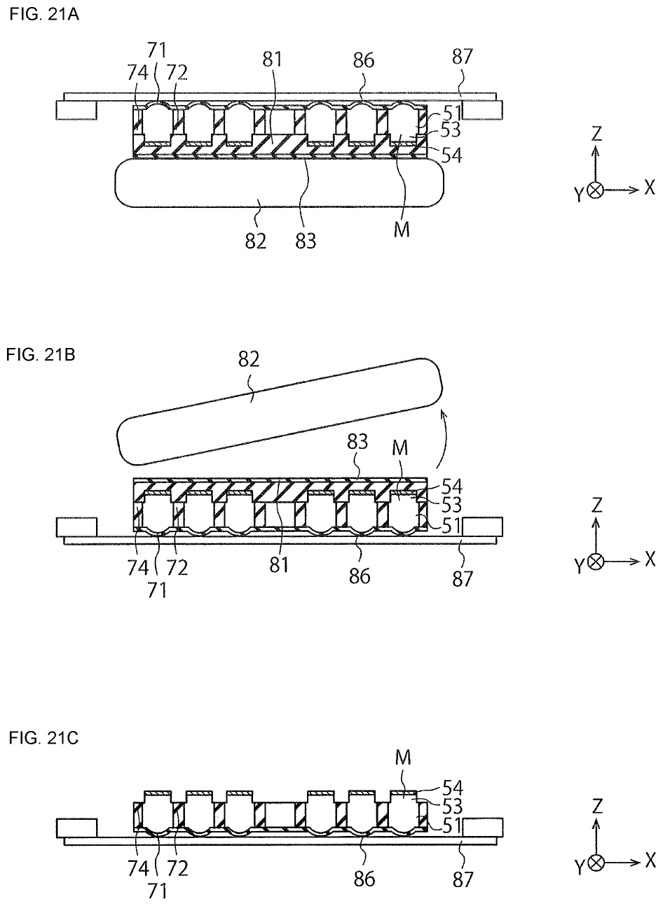

Next, a dicing tape of a mount device 87 is adhered to the substrate 51 (A of FIG. 21), and then the substrate 51 is turned upside down (B of FIG. 21). As a result, the substrate 51 is mounted on the dicing tape of the mount device 87 and fixed to a dicing frame of the mount device 87.

Next, the support substrate 82 is degassed from the substrate 51 using UV laser light (B of FIG. 21). In the present embodiment, the release layer 83 is irradiated with the UV laser light transmitted through the support substrate 82. As a result, the release layer 83 is decomposed (ablated) by the UV laser light, and the support substrate 82 is peeled off from the substrate 51. Next, the adhesive material 81 and the release layer 83 are removed by cleaning (C of FIG. 21).

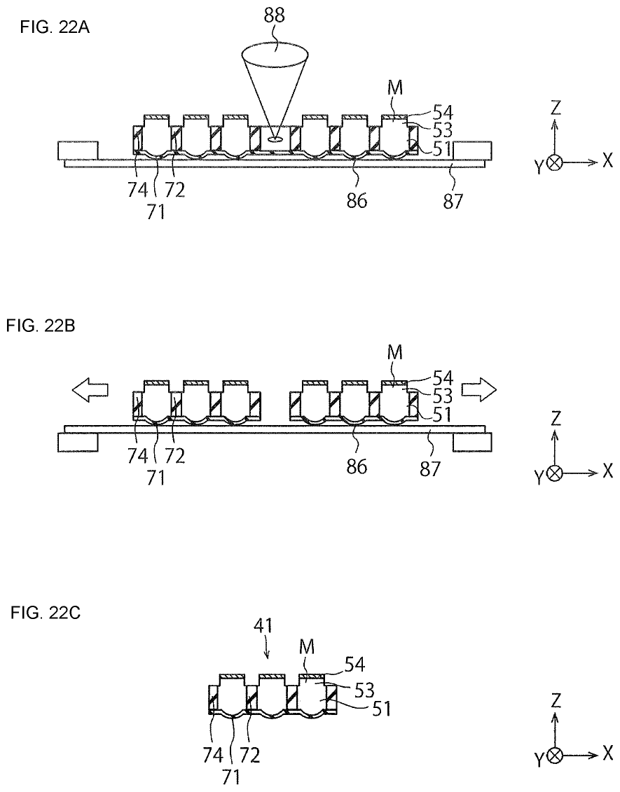

Next, using the laser device 88 for stealth dicing, a dicing line area in the substrate 51 is irradiated with laser light (A of FIG. 22), and as a result, the substrate 51 is cut along the dicing line.

Next, expanding processing is performed by the mount device 87 (B of FIG. 22). As a result, the substrate 51 is divided into a plurality of LD chips 41 (C of FIG. 22).

In this way, the LD chip 41 illustrated in FIG. 14 is manufactured. This LD chip 41 is then arranged on the LDD substrate 42 via a plurality of bumps 48. In this way, the light emitting device 1 illustrated in FIG. 14 is manufactured.

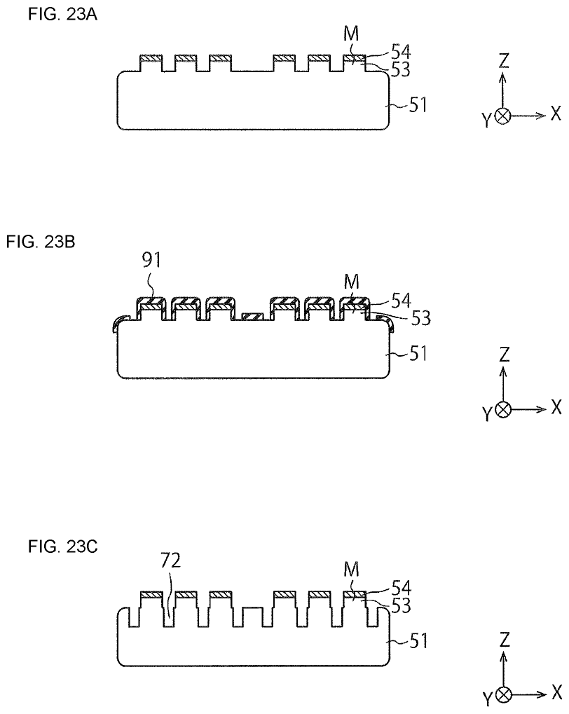

FIGS. 23 to 26 are cross-sectional views illustrating a method for manufacturing the light emitting device 1 of a modification of the second embodiment. In the following description, description of common points between the method illustrated in FIGS. 17 to 22 and the method illustrated in FIGS. 23 to 26 will be appropriately omitted.

First, the laminated film 52, the plurality of light emitting elements 53, the plurality of anode electrodes 54, the plurality of cathode electrodes 55, and the like are formed on the upper surface of the substrate (wafer) 51 (A of FIG. 23). However, the laminated film 52 and the cathode electrode 55 are not illustrated. A of FIG. 23 further illustrates the plurality of mesa portions M described above.

Next, a resist film 91 is formed on the substrate 51, and the resist film 91 is patterned (B of FIG. 23). Next, the grooves 72 are formed in the substrate 51 by dry etching using the resist film 91 as a mask (C of FIG. 23). The grooves 72 of the present modification are formed so as to penetrate the substrate 51 by thinning the substrate 51 to be described later.

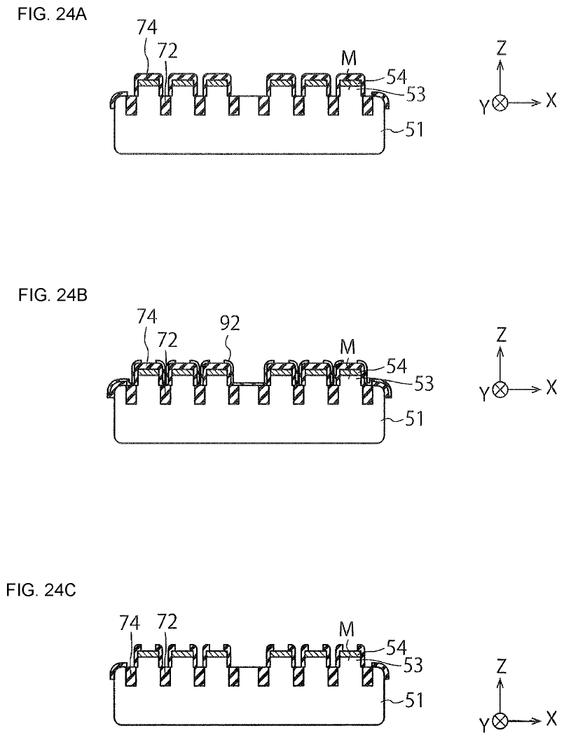

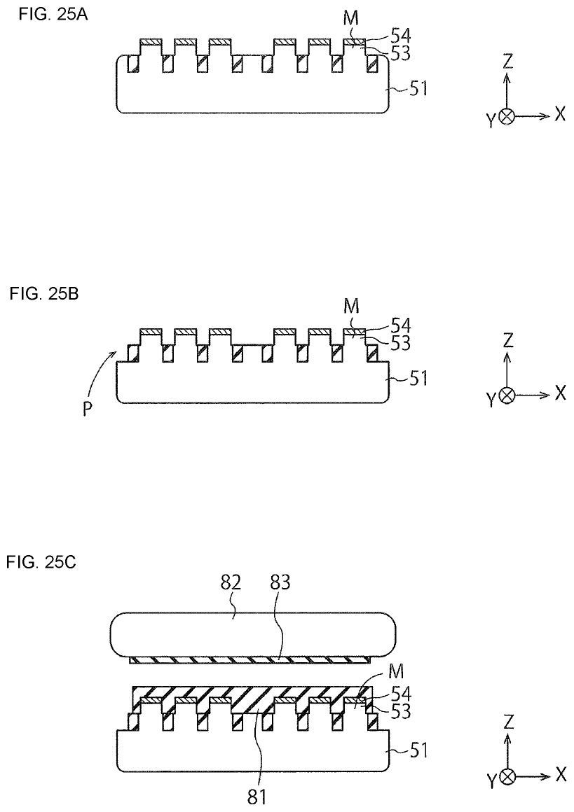

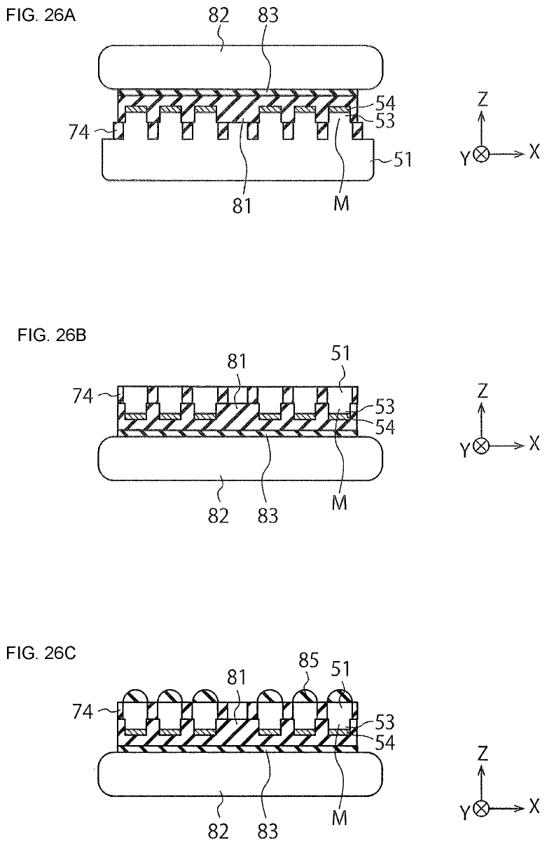

Next, the insulating film 74 is formed on the substrate 51 (A of FIG. 24), and a resist film 92 is formed on the insulating film 74 (B of FIG. 24). Next, the resist film 92 is patterned (B of FIG. 24), and a part of the insulating film 74 outside the grooves 72 is removed by dry etching using the resist film 92 as a mask (C of FIG. 24). Specifically, the insulating film 74 is removed from the upper surfaces of the anode electrode 54 and the cathode electrode 55 (not illustrated). As a result, the insulating film 74 is embedded in the grooves 72. Note that, in A of FIG. 25 to C of FIG. 26 to be described later, illustration of the insulating film 74 remaining outside the grooves 72 is omitted for easy viewing of the drawings. A of FIG. 25 illustrates the same state as the state illustrated in C of FIG. 25, but the illustration of the insulating film 74 remaining outside the grooves 72 is omitted.

Next, trimming processing of the edge portion of the substrate 51 is performed (B of FIG. 25). B of FIG. 25 illustrates a trimming portion P of the substrate 51.

Next, the adhesive material 81 is applied to the upper surface of the substrate 51 so as to cover the mesa portions M and the like (C of FIG. 25). Next, the release layer 83 is applied to the support substrate 82 (C of FIG. 25), and the substrate 51 and the support substrate 82 are bonded via the adhesive material 81 and the release layer 83 (A of FIG. 26).

Next, after the substrate 51 and the support substrate 82 are turned upside down, the substrate 51 is thinned (B of FIG. 26). As a result, the grooves 72 penetrate the substrate 51. Next, the resist film 85 is formed on the substrate 51, the resist film 85 is patterned, and the patterned resist film 85 is reflowed by heat treatment (C of FIG. 26). As a result, the resist film 85 is processed into a shape similar to that of the lens 71.

Thereafter, the processes illustrated in B of FIG. 20 to C of FIG. 22 are performed. In this way, the LD chip 41 illustrated in FIG. 14 is manufactured. This LD chip 41 is then arranged on the LDD substrate 42 via the plurality of bumps 48. In this way, the light emitting device 1 illustrated in FIG. 14 is manufactured.

Note that the steps illustrated in A of FIG. 23 to B of FIG. 24, that is, the step of forming the grooves 72 and the insulating film 74 may be performed before performing the process illustrated in A of FIG. 22 instead of performing the process illustrated in A of FIG. 22. That is, the grooves 72 and the insulating film 74 may be formed before the light emitting element 53 is formed, instead of being formed after the light emitting element 53 is formed.

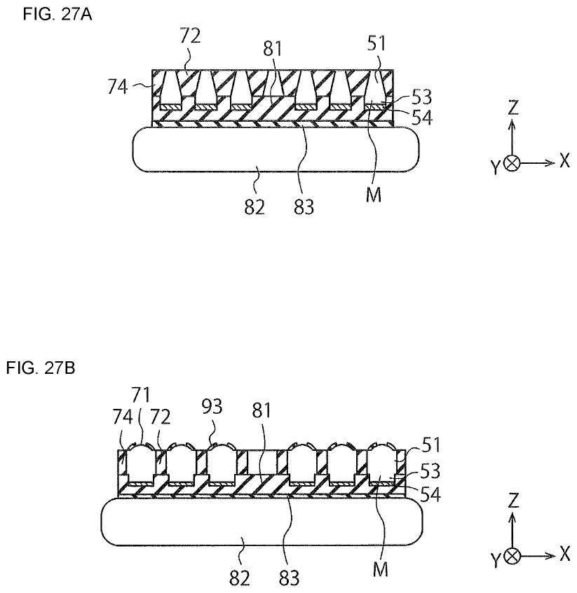

FIG. 27 is a cross-sectional view illustrating a method for manufacturing the light emitting device 1 of another modification of the second embodiment.

A of FIG. 27 illustrates the same state as the state illustrated in C of FIG. 19. However, the side surface of the groove 72 illustrated in A of FIG. 27 has a forward tapered shape. In this manner, the groove 72 may be formed such that the side surface thereof has a forward tapered shape.

B of FIG. 27 illustrates the same state as the state illustrated in C of FIG. 20. However, the lens 71 illustrated in B of FIG. 27 is partially covered with a light-shielding film 93 instead of being entirely covered with the antireflection film 86. The light-shielding film 93 covers a part of the upper surface of each lens 71 and forms an aperture of each lens 71. In the present modification, light directed to each lens 71 enters each lens 71 through this aperture. The light-shielding film 93 is formed of, for example, a metal film having a light shielding property. As described above, a part of the upper surface of the lens 71 may be covered with the light-shielding film 93.

As described above, the light emitting device 1 of the present embodiment includes the grooves 72 having the above-described shape. For example, the groove 72 of the present embodiment has the side surface Sa having an inclination angle of 80 degrees or more and 100 degrees or less, similarly to the groove 72 of the first embodiment. For example, the depth d of the groove 72 of the present embodiment is set to a value at which the light emitted from the light emitting element 53 does not enter the deepest portion of the groove surface of the groove 72, similarly to the depth d of the groove 72 of the first embodiment. Therefore, according to the present embodiment, the light emitted from the light emitting element 53 can be suitably incident on the lens 71.

Note that the light emitting devices 1 of the first and second embodiments are used as a light source of the distance measuring device 101, but may be used in another mode. For example, the light emitting devices 1 of these embodiments may be used as a light source of an optical apparatus such as a printer, or may be used as a lighting device.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A light emitting device including:
a substrate;
a plurality of light emitting elements provided on a first surface side of the substrate; and
a plurality of lenses provided on a second surface side of the substrate,
in which the substrate includes a first groove having a shape surrounding a first lens included in the plurality of lenses,
the first groove has a first side surface provided on the first lens side and a second side surface provided on an opposite side of the first lens, and
an inclination angle of the first side surface with respect to the first surface or the second surface is 80 degrees or more and 100 degrees or less.
   (2)

The light emitting device according to (1), in which an inclination angle of the second side surface with respect to the first surface or the second surface is 80 degrees or more and 100 degrees or less.

(3)

The light emitting device according to (1), in which the first groove has a bottom surface between the first side surface and the second side surface.

(4)

The light emitting device according to (1), in which the first side surface and the second side surface are in contact with each other in the first groove.

(5)

The light emitting device according to (1), in which the first groove penetrates the substrate.

(6)

The light emitting device according to (1), in which the first groove has a depth at which light emitted from the light emitting element does not enter a deepest portion of a groove surface of the first groove.

(7)

The light emitting device according to (1), in which the first groove has a width equal to or larger than a wavelength of light emitted from the light emitting element.

(8)

The light emitting device according to (1), in which the first groove has a shape in which light emitted from the light emitting element is totally reflected by the first side surface.

(9)

The light emitting device according to (1), further including an insulating film provided in the first groove.

(10)

The light emitting device according to (9), in which a refractive index of the insulating film is 2.3 or less.

(11)

The light emitting device according to (1),
in which the substrate further includes a second groove having a shape surrounding a second lens included in the plurality of lenses,
the second groove has a third side surface provided on the second lens side and a fourth side surface provided on an opposite side of the second lens, and
an inclination angle of the third side surface with respect to the first surface or the second surface is 80 degrees or more and 100 degrees or less.
   (12)

The light emitting device according to (11), in which an inclination angle of the fourth side surface with respect to the first surface or the second surface is 80 degrees or more and 100 degrees or less.

(13)

The light emitting device according to (11), in which the second groove is separated from the first groove.

(14)

The light emitting device according to (11), in which the second groove is connected to the first groove.

(15)

The light emitting device according to (1), in which the plurality of lenses is provided on the second surface of the substrate as parts of the substrate.

(16)

A light emitting device including:
a substrate;
a plurality of light emitting elements provided on a first surface side of the substrate; and
a plurality of lenses provided on a second surface side of the substrate,
in which the substrate includes a groove provided between the lenses, and
the groove has a depth at which light emitted from the light emitting element does not enter a deepest portion of a groove surface of the groove.
   (17)

A method for manufacturing a light emitting device, including:
forming a plurality of light emitting elements on a first surface side of a substrate;
forming a plurality of lenses on a second surface side of the substrate; and
forming, in the substrate, a first groove having a shape surrounding a first lens included in the plurality of lenses,
in which the first groove is formed to have a first side surface provided on the first lens side and a second side surface provided on an opposite side of the first lens, and
an inclination angle of the first side surface with respect to the first surface or the second surface is set to 80 degrees or more and 100 degrees or less.
   (18)

The method for manufacturing a light emitting device according to (17), in which the first groove is formed in the substrate from the second surface side of the substrate.

(19)

The method for manufacturing a light emitting device according to (17), in which the first groove is formed in the substrate from the first surface side of the substrate.

(20)

The method for manufacturing a light emitting device according to (17), further including forming a light-shielding film covering a part of an upper surface of each of the lenses on each of the lenses.

(21)

A distance measuring device including:
a light emitting unit that includes a plurality of light emitting elements that generate light and irradiates a subject with the light from the light emitting elements;
a light receiving unit that receives light reflected from the subject; and
a distance measuring unit that measures a distance to the subject on a basis of the light received by the light receiving unit, in which the light emitting device includes:
a substrate;
the plurality of light emitting elements provided on a first surface side of the substrate; and
a plurality of lenses provided on a second surface side of the substrate,
the substrate includes a first groove having a shape surrounding a first lens included in the plurality of lenses,
the first groove has a first side surface provided on the first lens side and a second side surface provided on an opposite side of the first lens, and
an inclination angle of the first side surface with respect to the first surface or the second surface is 80 degrees or more and 100 degrees or less.
   (22)

A distance measuring device including:
a light emitting unit that includes a plurality of light emitting elements that generate light and irradiates a subject with the light from the light emitting elements;
a light receiving unit that receives light reflected from the subject; and
a distance measuring unit that measures a distance to the subject on a basis of the light received by the light receiving unit,
in which the light emitting unit includes:
a substrate;
a plurality of light emitting elements provided on a first surface side of the substrate; and
a plurality of lenses provided on a second surface side of the substrate,
the substrate includes a groove provided between the lenses, and
the groove has a depth at which light emitted from the light emitting element does not enter a deepest portion of a groove surface of the groove.

### REFERENCE SIGNS LIST

1 Light emitting device
41 LD chip
42 LDD substrate
43 Mounting substrate
44 Heat dissipation substrate
45 Correction lens holding unit
46 Correction lens
47 Wiring
48 Bump
51 Substrate
52 Laminated film
53 Light emitting element
54 Anode electrode
55 Cathode electrode
61 Substrate
62 Connection pad
71 Lens
72 Groove
73 Light-shielding film
74 Insulating film
81 Adhesive material
82 Support substrate
83 Release layer
84 Resist film
85 Resist film
86 Antireflection film
87 Mount device
88 Laser device
91 Resist film
92 Resist film
93 Light-shielding film
101 Distance measuring device
102 Light emitting unit
102a Light emitting element
103 Drive unit
104 Power supply circuit
105 Light-emitting side optical system
106 Light-receiving side optical system
107 Light receiving unit
108 Signal processing unit
109 Control unit
109a Distance measuring unit
110 Temperature detection unit

1. A light emitting device comprising:
a substrate;
a plurality of light emitting elements provided on a first surface side of the substrate; and
a plurality of lenses provided on a second surface side of the substrate,
wherein the substrate includes a first groove having a shape surrounding a first lens included in the plurality of lenses,
the first groove has a first side surface provided on the first lens side and a second side surface provided on an opposite side of the first lens, and
an inclination angle of the first side surface with respect to the first surface or the second surface is 80 degrees or more and 100 degrees or less.

2. The light emitting device according to claim 1, wherein an inclination angle of the second side surface with respect to the first surface or the second surface is 80 degrees or more and 100 degrees or less.

3. The light emitting device according to claim 1, wherein the first groove has a bottom surface between the first side surface and the second side surface.

4. The light emitting device according to claim 1, wherein the first side surface and the second side surface are in contact with each other in the first groove.

5. The light emitting device according to claim 1, wherein the first groove penetrates the substrate.

6. The light emitting device according to claim 1, wherein the first groove has a depth at which light emitted from the light emitting element does not enter a deepest portion of a groove surface of the first groove.

7. The light emitting device according to claim 1, wherein the first groove has a width equal to or larger than a wavelength of light emitted from the light emitting element.

8. The light emitting device according to claim 1, wherein the first groove has a shape in which light emitted from the light emitting element is totally reflected by the first side surface.

9. The light emitting device according to claim 1, further comprising an insulating film provided in the first groove.

10. The light emitting device according to claim 9, wherein a refractive index of the insulating film is 2.3 or less.

11. The light emitting device according to claim 1,
wherein the substrate further includes a second groove having a shape surrounding a second lens included in the plurality of lenses,
the second groove has a third side surface provided on the second lens side and a fourth side surface provided on an opposite side of the second lens, and
an inclination angle of the third side surface with respect to the first surface or the second surface is 80 degrees or more and 100 degrees or less.

12. The light emitting device according to claim 11, wherein an inclination angle of the fourth side surface with respect to the first surface or the second surface is 80 degrees or more and 100 degrees or less.

13. The light emitting device according to claim 11, wherein the second groove is separated from the first groove.

14. The light emitting device according to claim 11, wherein the second groove is connected to the first groove.

15. The light emitting device according to claim 1, wherein the plurality of lenses is provided on the second surface of the substrate as parts of the substrate.

16. A light emitting device comprising:
a substrate;
a plurality of light emitting elements provided on a first surface side of the substrate; and
a plurality of lenses provided on a second surface side of the substrate,
wherein the substrate includes a groove provided between the lenses, and
the groove has a depth at which light emitted from the light emitting element does not enter a deepest portion of a groove surface of the groove.

17. A method for manufacturing a light emitting device, comprising:
forming a plurality of light emitting elements on a first surface side of a substrate;
forming a plurality of lenses on a second surface side of the substrate; and
forming, in the substrate, a first groove having a shape surrounding a first lens included in the plurality of lenses,
wherein the first groove is formed to have a first side surface provided on the first lens side and a second side surface provided on an opposite side of the first lens, and
an inclination angle of the first side surface with respect to the first surface or the second surface is set to 80 degrees or more and 100 degrees or less.

18. The method for manufacturing a light emitting device according to claim 17, wherein the first groove is formed in the substrate from the second surface side of the substrate.

19. The method for manufacturing a light emitting device according to claim 17, wherein the first groove is formed in the substrate from the first surface side of the substrate.

20. The method for manufacturing a light emitting device according to claim 17, further comprising forming a light-shielding film covering a part of an upper surface of each of the lenses on each of the lenses.

21. A distance measuring device comprising:
a light emitting unit that includes a plurality of light emitting elements that generate light and irradiates a subject with the light from the light emitting elements;
a light receiving unit that receives light reflected from the subject; and
a distance measuring unit that measures a distance to the subject on a basis of the light received by the light receiving unit,
wherein the light emitting unit includes:
a substrate;
the plurality of light emitting elements provided on a first surface side of the substrate; and
a plurality of lenses provided on a second surface side of the substrate,
the substrate includes a first groove having a shape surrounding a first lens included in the plurality of lenses,
the first groove has a first side surface provided on the first lens side and a second side surface provided on an opposite side of the first lens, and
an inclination angle of the first side surface with respect to the first surface or the second surface is 80 degrees or more and 100 degrees or less.

22. A distance measuring device comprising:
a light emitting unit that includes a plurality of light emitting elements that generate light and irradiates a subject with the light from the light emitting elements;
a light receiving unit that receives light reflected from the subject; and
a distance measuring unit that measures a distance to the subject on a basis of the light received by the light receiving unit,
wherein the light emitting unit includes:
a substrate;
a plurality of light emitting elements provided on a first surface side of the substrate; and
a plurality of lenses provided on a second surface side of the substrate,
the substrate includes a groove provided between the lenses, and
the groove has a depth at which light emitted from the light emitting element does not enter a deepest portion of a groove surface of the groove.
